(19) United States
(12) Patent Application Publication
(10) Pub. No.: US 2025/0071965 A1
(43) Pub. Date: Feb. 27, 2025

(54) SEMICONDUCTOR DEVICE AND METHOD FOR FABRICATING THE SAME

(71) Applicant: SK hynix Inc., Gyeonggi-do (KR)

(72) Inventors: Min Chul SUNG, Gyeonggi-do (KR); Sei Yon KIM, Gyeonggi-do (KR)

(21) Appl. No.: 18/411,022

(22) Filed: Jan. 12, 2024

(30) Foreign Application Priority Data
Aug. 24, 2023 (KR) 10-2023-0111117

(51) Int. Cl. H10B 12/00

(52) U.S. Cl. CPC H10B 12/00

(57) ABSTRACT

A semiconductor device includes a bit line; a plurality of first semiconductor pillars disposed over the bit line; a plurality of first cell contact plugs disposed between the first semiconductor pillars; a plurality of second semiconductor pillars coupled to the first cell contact plugs; a plurality of second cell contact plugs disposed between the second semiconductor pillars and coupled to the first semiconductor pillars; and a plurality of capacitors respectively coupled to the second semiconductor pillars and the second cell contact plugs.

### CROSS-REFERENCE TO RELATED APPLICATIONS

The present application claims priority under 35 U.S.C 119(a) to Korean Patent Application No. 10-2023-0111117, filed on Aug. 24, 2023, which is incorporated herein by reference in its entirety.

### BACKGROUND

### 1. Field

Various embodiments of the present invention relate to a semiconductor device, and more particularly, to a semiconductor device including vertical transistors, and a method for fabricating the semiconductor device.

### 2. Description of the Related Art

For high integration of semiconductor devices, a transistor with a vertical channel (which, hereinafter, may be simply referred to as a ‘vertical transistor’) has been proposed.

Vertical transistors using monocrystalline silicon as a channel have limitations in terms of integration. Also, electrical characteristics may deteriorate due to gate-induced drain leakage (GIDL) occurring in an overlapping area between a source/drain and a gate and junction leakage of a PN junction. Thus, improved structures for improved integration and performance are needed.

### SUMMARY

Embodiments of the present invention are directed to a highly integrated semiconductor device, and a method for fabricating the same.

In accordance with an embodiment of the present invention, a semiconductor device includes: a bit line; a plurality of first semiconductor pillars disposed over the bit line; a plurality of first cell contact plugs disposed between the first semiconductor pillars; a plurality of second semiconductor pillars coupled to the first cell contact plugs; a plurality of second cell contact plugs disposed between the second semiconductor pillars and coupled to the first semiconductor pillars; and a plurality of capacitors respectively coupled to the second semiconductor pillars and the second cell contact plugs.

In accordance with another embodiment of the present invention, a method for fabricating a semiconductor device includes: forming a bit line over a substrate; forming first semiconductor pillars over the bit line; forming a plurality of first cell contact plugs that are coupled to the bit line between the first semiconductor pillars; forming second semiconductor pillars over the first cell contact plugs; forming a plurality of second cell contact plugs disposed between the second semiconductor pillars and coupled to the first semiconductor pillars; and forming a plurality of capacitors that are respectively coupled to the second semiconductor pillars and the second cell contact plugs. The method further comprising forming a first inter-layer dielectric layer between the first semiconductor pillars covering the bit line; forming a first contact hole exposing the bit line in the first inter-layer dielectric layer; forming a first contact spacer on a sidewall of the first contact hole; and filling the first contact hole with a conductive layer to form the first cell contact plugs over the first contact spacer. The method further comprising forming a second inter-layer dielectric layer between the second semiconductor pillars; forming a second contact hole exposing upper surfaces of the first semiconductor pillars in the second inter-layer dielectric layer; forming a second contact spacer on a sidewall of the second contact hole; and filling the second contact hole with conductive layers to form the second cell contact plugs over the second contact spacer. The method further comprising before forming the first cell contact plugs, forming a first gate dielectric layer on sidewalls of the first semiconductor pillars; and forming a first vertical gate of a double structure disposed on both sidewalls of each of the first semiconductor pillars over the first gate dielectric layer. The method further comprising before forming the second cell contact plugs, forming a second gate dielectric layer on sidewalls of the second semiconductor pillars; and forming a second vertical gate of a double structure disposed on the sidewalls of the second semiconductor pillars over the second gate dielectric layer. the forming the bit line and the forming the first semiconductor pillars include forming a conductive layer over the substrate; forming an oxide semiconductor stack over the conductive layer; forming an oxide semiconductor line by etching the oxide semiconductor stack; etching the conductive layer to form the bit line; and etching the oxide semiconductor line in a direction intersecting with the bit line to form the first semiconductor pillars. The method further comprising: forming tapered double vertical gates on both sidewalls of each of the first semiconductor pillars and on both sidewalls of each of the second semiconductor pillars.

In accordance with another embodiment of the present invention, a semiconductor device includes: a horizontal conductive line, a first level including first semiconductor pillars and first contact plugs that are disposed over the horizontal conductive line, a second level including second semiconductor pillars and second contact plugs that are disposed over the first level; and a third level disposed over the second level, wherein the second contact plugs are vertically stacked over the first semiconductor pillars, and the second semiconductor pillars are vertically stacked over the first contact plugs. The first semiconductor pillars and the first contact plugs may be spaced apart from each other, and the second semiconductor pillars and the second contact plugs may be spaced apart from each other. The first level may include an array of a plurality of first vertical channel transistors. The second level may include an array of a plurality of second vertical channel transistors. The third level may include an array of a plurality of capacitors. It may further include a double-structured first level vertical conductive line disposed on both sidewalls of each of the first semiconductor pillars. It may further include a double-structured second level vertical conductive line disposed on both sidewalls of each of the second semiconductor pillars.

These and other features and advantages will become better understood by the following figures and detailed description of embodiments of the invention.

### BRIEF DESCRIPTION OF THE DRAWINGS

FIG. 1 is a schematic cross-sectional view illustrating a semiconductor device in accordance with an embodiment of the present invention.

FIG. 2A is a schematic plan view taken along a line A1-A′ shown in FIG. 1.

FIG. 2B is a schematic plan view taken along a line A2-A2′ shown in FIG. 1.

FIG. 2C is a schematic cross-sectional view taken along a line A3-A3′ shown in FIG. 1.

FIG. 2D is a schematic cross-sectional view taken along a line A4-A4′ shown in FIG. 2C.

FIG. 3A is a cross-sectional view illustrating a first vertical transistor.

FIG. 3B is a cross-sectional view illustrating a second vertical transistor.

FIGS. 4 to 32 illustrate a method for fabricating a semiconductor device in accordance with an embodiment of the present invention.

FIGS. 33 to 35 illustrate a method for fabricating a semiconductor device in accordance with another embodiment of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout this disclosure, like reference numerals refer to like parts throughout the various figures and embodiments of the present invention.

The drawings are not necessarily to scale and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

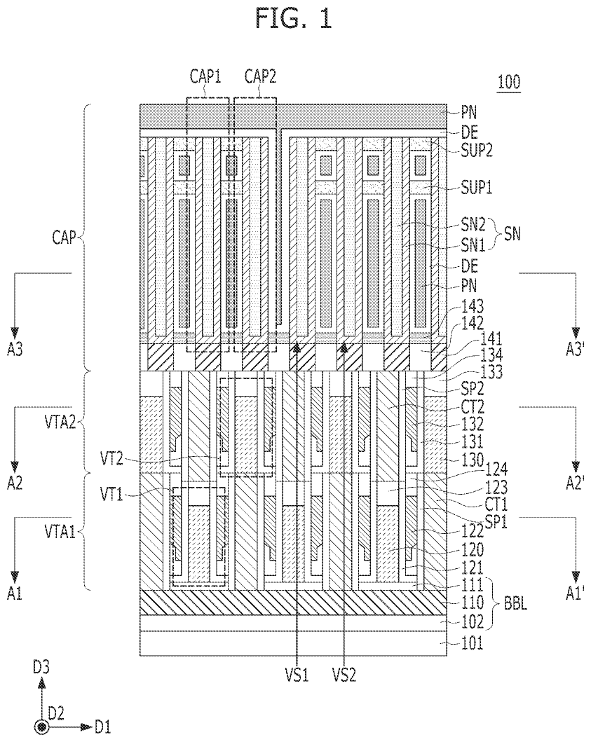

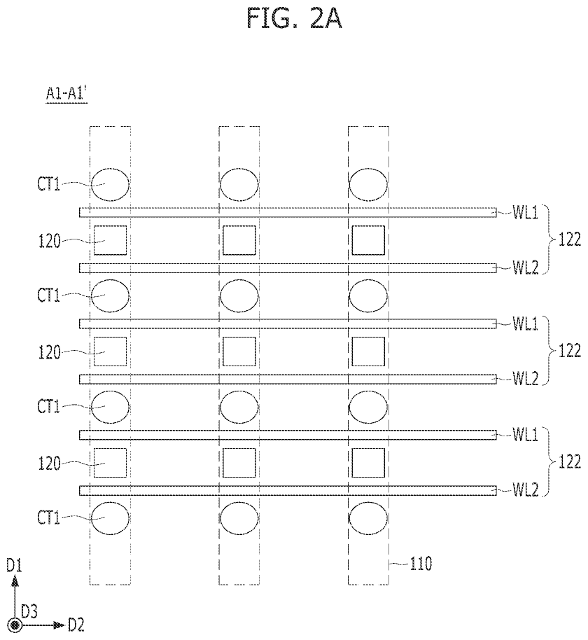

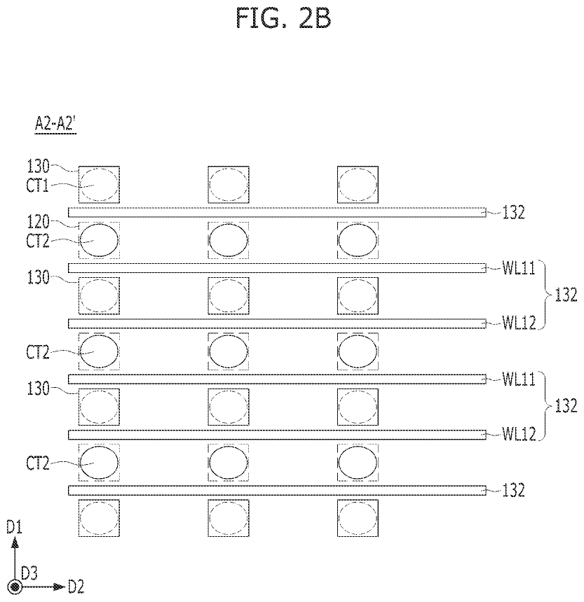

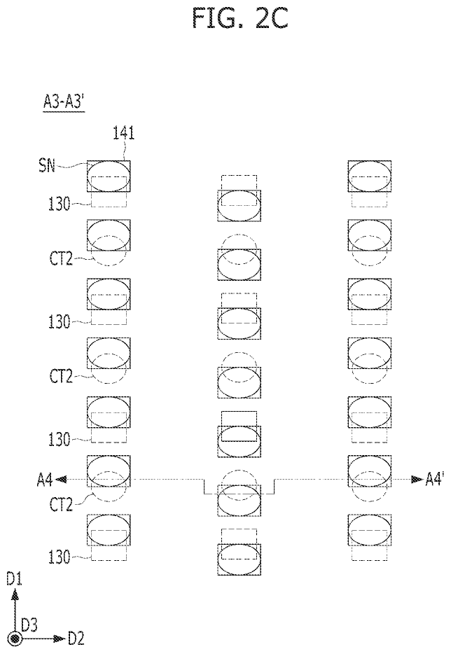

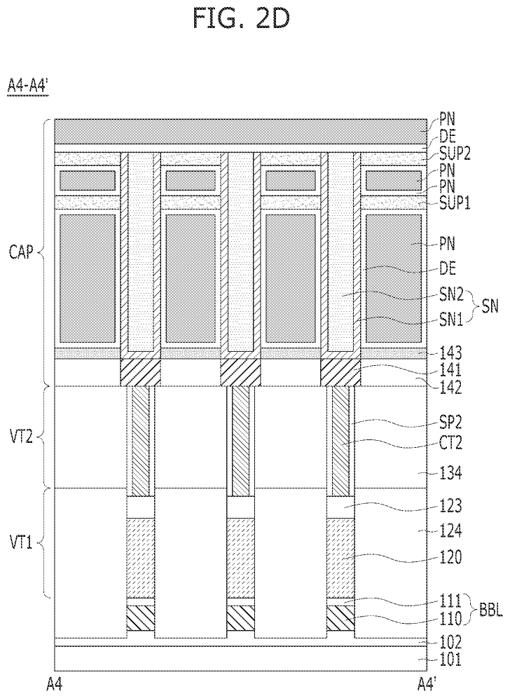

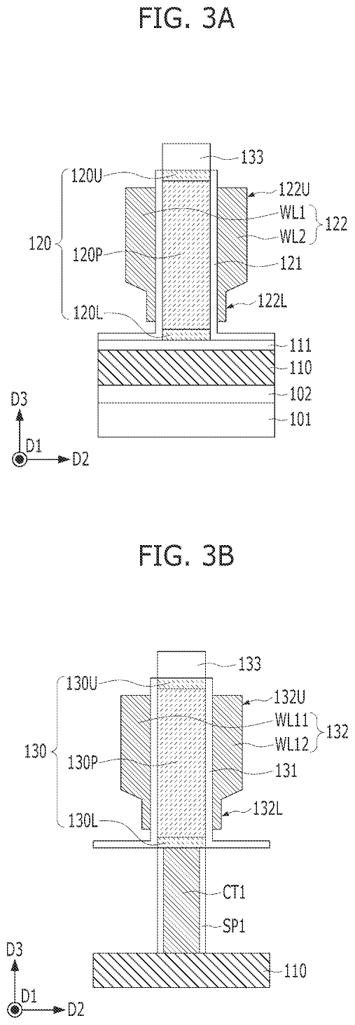

FIG. 1 is a schematic cross-sectional view illustrating a semiconductor device 100. FIG. 2A is a schematic plan view taken along a line A1-A′ shown in FIG. 1. FIG. 2B is a schematic plan view taken along a line A2-A2′ shown in FIG. 1. FIG. 2C is a schematic cross-sectional view taken along a line A3-A3′ shown in FIG. 1. FIG. 2D is a schematic cross-sectional view taken along a line A4-A4′ shown in FIG. 2C. FIG. 3A is a detailed cross-sectional view illustrating a first vertical transistor. FIG. 3B is a detailed cross-sectional view illustrating a second vertical transistor.

Referring now to FIGS. 1, 2A, 2B, 2C, 2D, 3A, and 3B, the semiconductor device 100 may include a horizontal conductive line 110, and first, second and third levels. The first level includes first semiconductor pillars 120 and first cell contact plugs CT1 disposed over the horizontal conductive line 110. The second level is disposed over the first level and includes second semiconductor pillars 130 and second cell contact plugs CT2 disposed over the first level. The third level is disposed over the second level. The second cell contact plugs CT2 may be vertically stacked over the first semiconductor pillars 120, and the second semiconductor pillars 130 may be vertically stacked over the first cell contact plugs CT1. The first semiconductor pillars 120 and the first cell contact plugs CT1 may be spaced apart from each other. The second semiconductor pillars 130 and the second cell contact plugs CT2 may be spaced apart from each other. The first level may include an array VTA1 of a plurality of first vertical transistors VT1. The second level may include an array VTA2 of a plurality of second vertical transistors VT2. The third level may include an array of a plurality of data storage elements CAP1 and CAP2. A double-structured first level-vertical conductive line 122 may be disposed on both sidewalls of the first semiconductor pillars 120. A double-structured second level-vertical conductive line 132 may be disposed on both sidewalls of the second semiconductor pillars 130. The first level-vertical conductive line 122 and the second level-vertical conductive line 132 may extend in a first direction D1.

Hereinafter, the first horizontal conductive line 110 may be simply referred to as ‘a bit line 110’. The first level-vertical conductive line 122 and the second level-vertical conductive line 132 may be simply referred to as ‘a first vertical gate 122 and a second vertical gate 132’, respectively.

The semiconductor device 100 may include a substrate 101, a buried conductive multi-layer line structure BBL, a first vertical transistor array VTA1, a second vertical transistor array VTA2, and a data storage element array CAP. The semiconductor device 100 may include a memory cell array.

The buried conductive multi-layer line structure BBL may include a stack of a bit line 110 and a barrier layer 111 disposed over the bit line 110. The buried conductive multi-layer line structure BBL may be disposed over the substrate 101, and the buffer layer 102 may be disposed between the substrate 101 and the buried conductive multi-layer line structure BBL. Referring to FIG. 2A, the buried conductive multi-layer line structure BBL may extend in the first direction D1. The first direction D1 may be in some embodiments a horizontal direction.

The first vertical transistor array VTA1 may include a three-dimensional array of a plurality of first vertical transistors VT1. Each first vertical transistor VT1 may include a first semiconductor pillar 120, a first gate dielectric layer 121 formed on both sidewalls of the first semiconductor pillar 120, and a first vertical gate 122 formed over the first gate dielectric layer 121. The first vertical gate 122 may include a pair of a first tapered gate WL1 and a second tapered gate WL2. Each first vertical transistor VT1 may further include a first pillar pad 123 that is disposed over the first semiconductor pillar 120. Referring to FIG. 2A, the first tapered gate WL1 and the second tapered gate WL2 may extend in a second direction D2. The first vertical gate 122 may be referred to as a ‘first vertical word line’, and the first tapered gate WL1 and the second tapered gate WL2 may be referred to as a ‘first tapered word line and a second tapered word line,’ respectively.

The second vertical transistor array VTA2 may include a three-dimensional array of a plurality of second vertical transistors VT2. Each second vertical transistor VT2 may include a second semiconductor pillar 130, a second gate dielectric layer 131 formed on both sidewalls of the second semiconductor pillar 130, and a second vertical gate 132 formed over the second gate dielectric layer 131. The second vertical gate 132 may include a pair of a first tapered gate WL11 and a second tapered gate WL12. Each second vertical transistor VT2 may further include a second pillar pad 133 disposed over a corresponding second semiconductor pillar 130. Referring to FIG. 2B, the first tapered gate WL11 and the second tapered gate WL12 may extend in the second direction D2. The second vertical gate 122 may be referred to as a ‘second vertical word line’, and the first tapered gate WL11 and the second tapered gate WL12 may be referred to as ‘a first tapered word line’ and ‘a second tapered word line’, respectively.

The first and second semiconductor pillars 120 and 130 may extend vertically in a third direction D3. The first and second semiconductor pillars 120 and 130 may be referred to as active pillars or channel pillars.

The data storage element array CAP may include landing pads 141 disposed over the second vertical transistor array VTA2, first electrodes SN over the landing pads 141, a plurality of supporters SUP1 and SUP2 supporting the outer wall of the first electrodes SN, a dielectric layer DE formed over the first electrodes SN and the supporters SUP1 and SUP2, and a second electrode PN formed over the dielectric layer DE. The data storage element array CAP may include a capacitor array. For example, the data storage element array CAP may include a first capacitor array including a plurality of first capacitors CAP1 and a second capacitor array including a plurality of second capacitors CAP2. The individual first capacitors CAP1 and the individual second capacitors CAP2 may have the same structure and may include a first electrode SN, a dielectric layer DE, and a second electrode PN with the dielectric layer DE disposed between the first and second electrodes SN, PN. The first electrodes SN of the individual first capacitors CAP1 and the individual second capacitors CAP2 may have a pillar-type structure. The first electrodes SN of the first capacitors CAP1 and the second capacitors CAP2 may include a cylinder-shape electrode SN1 and a pillar-shape electrode SN2 that fills the interior of the cylinder-shape electrode SN1. Referring back to FIG. 2C, neighboring first electrodes SN may be arranged in a zig-zag arrangement to form an array of a honeycomb structure.

The landing pads 141 may be spaced apart from each other at a regular interval in the inter-layer dielectric layer 142 and may pass through the inter-layer dielectric layer 142 to contact the respective second contact plugs CT2 and second spacers SP2 at a bottom end thereof and the cylinder-shape electrodes SN1 at a top end thereof. An etch stop layer 143 may be disposed over the inter-layer dielectric layer 142.

The first vertical transistor array VTA1 may further include first cell contact plugs CT1. The first cell contact plugs CT1 may be disposed between the first vertical transistors VT1. The first cell contact plugs CT1 may be disposed between the first vertical gates 122 of the first vertical transistors VT1.

First contact spacers SP1 may be disposed on the outer walls of the first cell contact plugs CT1. The first contact spacers SP1 may surround the outer walls of the first cell contact plugs CT1. The first contact spacers SP1 may include a dielectric material, and the first cell contact plugs CT1 may include a conductive material. The first cell contact plugs CT1 may be electrically connected to the bit line 110 and the second semiconductor pillar 130. The first cell contact plugs CT1 may extend vertically from the bit line 110 in the third direction D3, and the second semiconductor pillars 130 may extend vertically from the first cell contact plugs CT1 in the third direction D3.

The second vertical transistor array VTA2 may further include second cell contact plugs CT2 disposed between the second vertical transistors VT2. Second contact spacers SP2 may be disposed on the outer walls of the second cell contact plugs CT2. The second contact spacers SP2 may surround the outer walls of the second cell contact plugs CT2. The second contact spacers SP2 may include a dielectric material, and the second cell contact plugs CT2 may include a conductive material. Referring back to FIG. 2D, the second cell contact plugs CT2 may be electrically connected to the first semiconductor pillars 120 through the first pillar pad 123. The first semiconductor pillars 120 may extend vertically from the bit line 110 in the third direction D3. The second cell contact plugs CT2 may also extend vertically from the first semiconductor pillars 120 in the third direction D3.

The first vertical structure VS1 indicated by a vertical arrow includes the bit line 110, the first semiconductor pillar 120, the second cell contact plug CT2, and the landing pad 141 stacked in the mentioned order and may be coupled to the first capacitor CAP1. The second vertical gate 132 and the second cell contact plugs CT2 may be isolated from each other by the second contact spacer SP2.

The second vertical structure VS2 indicated by another vertical arrow includes the bit line 110, the first cell contact plug CT1, the second semiconductor pillar 130, and the landing pad 141 stacked in the mentioned order and may be coupled to the second capacitor CAP2. The first vertical gate 122 and the first cell contact plugs CT1 may be isolated from each other by the first contact spacer SP1.

The substrate 101 may be a material suitable for semiconductor processing. The substrate 101 may include a semiconductor substrate. The substrate 101 may be formed of a material containing silicon. The substrate 101 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 101 may also include another semiconductor material, such as germanium. The substrate 101 may include a III/V-group semiconductor substrate, for example, a compound semiconductor substrate, such as GaAs. The substrate 101 may include a silicon-on-insulator (SOI) substrate.

The buffer layer 102 may include silicon oxide, silicon nitride, or a combination thereof. To reduce parasitic capacitance, the buffer layer 102 may be formed of silicon oxide. For example, the buffer layer 102 may include Tetra Ethyl Ortho Silicate (TEOS).

The bit line 110 may extend horizontally in the first direction D1 over the buffer layer 102. The bit line 110 may include a metal-based material. The bit line 110 may include a metal, a metal nitride, a metal silicide, or a combination thereof. The bit line 110 may have a thickness of approximately 100 to 400 Å. The bit line 110 may include a tungsten layer.

The barrier layer 111 may include a metal, a metal nitride, a metal silicide, or a combination thereof. The barrier layer 111 may include titanium nitride, molybdenum, or ruthenium. The barrier layer 111 may have a thickness of approximately 10 to 50 Å. For example, the barrier layer 111 may include a titanium nitride layer.

Referring back to FIGS. 3A and 3B, the first semiconductor pillar 120 may include a first lower interface layer 120L, a first upper interface layer 120U, and a first channel layer 120P between the first lower interface layer 120L and the first upper interface layer 120U. The second semiconductor pillar 130 may be formed in the same structure as that of the first semiconductor pillar 120. The second semiconductor pillar 130 may include a second lower interface layer 130L, a second upper interface layer 130U, and a second channel layer 130P between the second lower interface layer 130L and the second upper interface layer 130U.

The first and second semiconductor pillars 120 and 130 may include an oxide semiconductor layer. The first and second semiconductor pillars 120 and 130 may be oxide semiconductor pillars. The first lower interface layer 120L, the first upper interface layer 120U, and the first channel layer 120P may include an oxide semiconductor layer. The second lower interface layer 130L, the second upper interface layer 130U, and the second channel layer 130P may include an oxide semiconductor layer.

The first vertical gate 122 and the second vertical gate 132 may have a tapered vertical word line structure.

The first and second lower interface layers 120L and 130L and the first and second upper interface layers 120U and 130U may include an oxide semiconductor material with a lower resistance than the first and second channel layers 120P and 130P. The first and second lower interface layers 120L and 130L and the first and second upper interface layers 120U and 130U may include a metallic-rich oxide semiconductor material, and the first and second channel layers 120P and 130P may include an oxygen-rich oxide semiconductor material. For example, the first and second channel layers 120P and 130P may include indium gallium zinc oxide (IGZO), indium tin zinc oxide (IZTO), or zinc tin oxide (ZTO), and the first and second lower interface layers 120L and 130L and the first and second upper interface layers 120U and 130U may include indium-rich IGZO. Indium-rich IGZO may refer to a material having an indium content higher than gallium (Ga) and zinc (Zn) in IGZO, for example, the indium content may be 40% or more.

The first and second channel layers 120P and 130P may include an oxide semiconductor material. The first and second channel layers 120P and 130P may contain indium. The first and second channel layers 120P and 130P may include IGZO. The first and second channel layers 120P and 130P may be formed to have a thickness of approximately 200 to 1000 Å.

The first and second lower interface layers 120L and 130L may include an oxide semiconductor material. The first and second lower interface layers 120L and 130L may contain indium. The first and second lower interface layers 120L and 130L may include an indium-rich oxide semiconductor material. For example, the first and second lower interface layers 120L and 130L may include indium-rich IGZO. The first and second lower interface layers 120L and 130L may be formed to have a thickness of approximately 10 to 50 Å.

The first and second upper interface layers 120U and 130U may include an oxide semiconductor material. The first and second upper interface layers 120U and 130U may contain indium. The first and second upper interface layers 120U and 130U may include an indium-rich oxide semiconductor material. For example, the first and second upper interface layers 120U and 130U may include indium-rich IGZO. The first and second upper interface layers 120U and 130U may be formed to have a thickness of approximately 10 to 50 Å.

The first and second semiconductor pillars 120 and 130 may extend vertically over the bit line 110 in the third direction D3. The first and second semiconductor pillars 120 and 130 may include the first and second lower interface layers 120L and 130L, the first and second channel layers 120P and 130P, and the first and second upper interface layers 120U and 130U that are stacked vertically in the mentioned order. The first and second lower interface layers 120L and 130L, the first and second channel layers 120P and 130P, and the first and second upper interface layers 120U and 130U may all include an oxide semiconductor material. The first and second lower interface layers 120L and 130L, the first and second channel layers 120P and 130P, and the first and second upper interface layers 120U and 130U may all include IGZO, and the first and second lower interface layers 120L and 130L and the first and second upper interface layers 120U and 130U may have a greater indium concentration than the first and second channel layers 120P and 130P. The first and second channel layers 120P and 130P may be IGZO, and the first and second lower interface layers 120L and 130L and the first and second upper interface layers 120U and 130U may be indium-rich IGZO. The first and second semiconductor pillars 120 and 130 may be referred to as active pillars.

The first vertical gate 122 may be disposed on a sidewall of the first semiconductor pillar 120. The first vertical gate 122 may have a double structure of the first tapered gate WL1 and the second tapered gate WL2. The first vertical gate 122 and the bit line 110 may extend in directions that intersect with each other. The first vertical gate 122 may have a reverse tapered shape. The reverse tapered shape may refer to a shape in which the width of the bottom portion is getting smaller than the width of the top portion. The first vertical gate 122 may include a first lower level portion 122L disposed adjacent to the bottom portion of the first semiconductor pillar 120 and a first upper level portion 122U disposed adjacent to the top portion of the first semiconductor pillar 120. The thickness of the first lower level portion 122L in the first direction D1 may be thinner than the thickness of the first upper level portion 122U. The first lower level portion 122L may be disposed adjacent to the first lower interface layer 120L, and the first upper level portion 122U may be disposed adjacent to the first upper interface layer 120U. The first lower level portion 122L and the first upper level portion 122U may be formed of the same material and may have an integrated structure.

The first vertical gate 122 may include a metal-based material. The first vertical gate 122 may include a metal, a metal nitride, or a combination thereof. The first vertical gate 122 may include tantalum nitride (TaN), titanium nitride (TiN), tungsten (W), tungsten nitride (WN), or a combination thereof.

The first gate dielectric layer 121 may include silicon oxide, silicon nitride, silicon oxynitride, a high-k material, or a combination thereof. The first gate dielectric layer 121 may be disposed between the first semiconductor pillar 120 and the first vertical gate 122. The first gate dielectric layer 121 may include a flat portion extending to be disposed between the lower level portion of the first vertical gate 122 and the bit line 110, and the flat portion of the first gate dielectric layer 121 may directly contact the barrier layer 111. The first vertical gate 122 may be referred to as a first tapered vertical gate or a first tapered vertical word line.

The second vertical gate 132 may be disposed on a sidewall of the second semiconductor pillar 130. The second vertical gate 132 may have a double structure of the first tapered gate WL11 and the second tapered gate WL12. The second vertical gate 132 and the bit line 110 may extend in directions that intersect with each other. The second vertical gate 132 may have a reverse tapered shape. The term ‘reverse tapered shape’ as used here refers to a shape in which the width of the bottom portion is getting smaller than the width of the top portion. The second vertical gate 132 may include a second lower level portion 132L disposed adjacent to the bottom portion of the second semiconductor pillar 130 and a second upper level portion 132U disposed adjacent to the top portion of the second semiconductor pillar 130. The thickness of the second lower level portion 132L in the first direction D1 may be thinner than the thickness of the second upper level portion 132U. The second lower level portion 132L may be disposed adjacent to the second lower interface layer 130L, and the second upper level portion 132U may be disposed adjacent to the second upper interface layer 130U. The second lower level portion 132L and the second upper level portion 132U may be formed of the same material and may have an integrated structure.

The second vertical gate 132 may include a metal-based material. The second vertical gate 132 may include a metal, a metal nitride, or a combination thereof. The second vertical gate 132 may include tantalum nitride (TaN), titanium nitride (TiN), tungsten (W), tungsten nitride (WN), or a combination thereof.

The second gate dielectric layer 131 may include silicon oxide, silicon nitride, silicon oxynitride, a high-k material, or a combination thereof. The second gate dielectric layer 131 may be disposed between the second semiconductor pillar 130 and the second vertical gate 132. The second gate dielectric layer 131 may include a flat portion extending to be disposed between the lower level portion of the second vertical gate 132 and the bit line 110, and the flat portion of the second gate dielectric layer 131 may directly contact the barrier layer 111. The second vertical gate 132 may be referred to as a second tapered vertical gate or a second tapered vertical word line.

The first and second cell contact plugs CT1 and CT2 may include a metal-based material. The first and second cell contact plugs CT1 and CT2 may include a metal, a metal nitride, or a combination thereof. The first and second cell contact plugs CT1 and CT2 may be formed of the same metal-based material. According to another embodiment of the present invention, the first and second cell contact plugs CT1 and CT2 may be formed of different metal-based materials.

The first and second contact spacers SP1 and SP2 may include a dielectric material. For example, the first and second contact spacers SP1 and SP2 may include silicon oxide, silicon nitride, or a combination thereof.

The first and second pillar pads 123 and 133 may include a metal-based material. The first and second pillar pads 123 and 133 may include a metal, a metal nitride, or a combination thereof. The first and second pillar pads 123 and 133 may be formed of the same metal-based material. According to another embodiment of the present invention, the first and second pillar pads 123 and 133 may be formed of different metal-based materials. The sidewalls of the first pillar pad 123 may be surrounded by the first gate dielectric layer 121. The sidewalls of the second pillar pad 133 may be surrounded by the second gate dielectric layer 131.

The landing pads 141 may include a metal-based material. The landing pads 141 may include a metal, a metal nitride, or a combination thereof. The landing pads 141 and the second cell contact plugs CT2 may partially overlap. The landing pads 141 and the second pillar pads 133 may partially overlap.

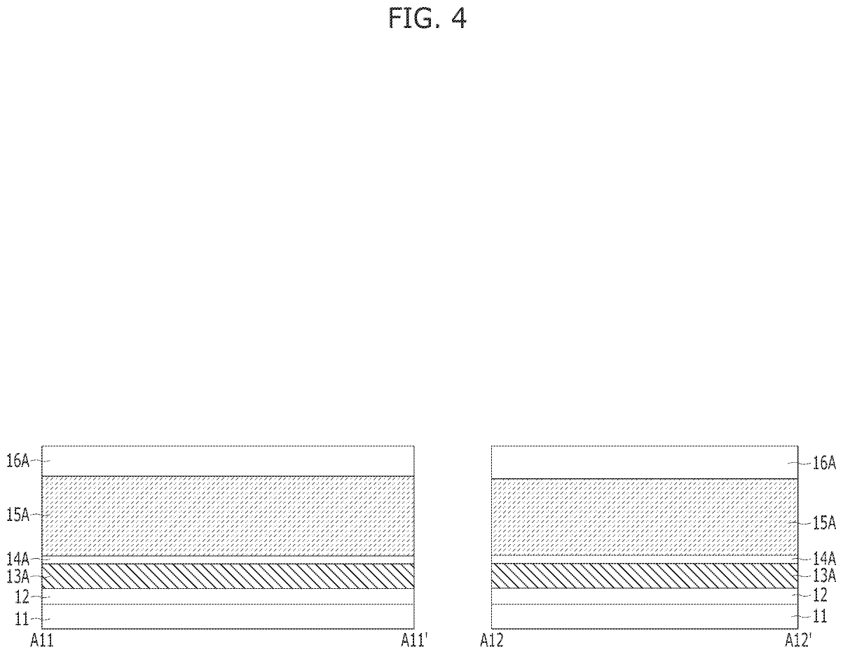

FIGS. 4 to 32 illustrate an example of a method for fabricating a semiconductor device in accordance with an embodiment of the present invention. Hereinafter, the views of an A11-A11′ direction are cross-sectional views in a direction crossing the bit line, and the views of an A12-A12′ direction are cross-sectional views in a direction that the bit line extends. For example, the views of the A11-A11′ direction are cross-sectional views taken in the second direction D3 shown in FIG. 1, and the views of the A12-A12′ direction are cross-sectional views taken in the first direction D1 shown in FIG. 1.

Referring to FIG. 4, a buffer layer 12 may be formed over a substrate 11. The substrate 11 may be a material suitable for semiconductor processing. The substrate 11 may include a semiconductor substrate. The substrate 11 may be formed of a material containing silicon. The substrate 11 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 11 may also include other semiconductor materials, such as germanium. The substrate 11 may include a III/V-group semiconductor substrate, for example, a compound semiconductor substrate, such as GaAs. The substrate 11 may include a silicon-on-insulator (SOI) substrate. The buffer layer 12 may include a dielectric material. The buffer layer 12 may include silicon oxide, silicon nitride, or a combination thereof.

A conductive layer 13A may be formed over the buffer layer 12. The conductive layer 13A may include a metal-based material. The conductive layer 13A may include a metal, a metal nitride, a metal silicide, or a combination thereof. The conductive layer 13A may be formed by atomic layer deposition (ALD), physical vapor deposition (PVD), or chemical vapor deposition (CVD). The conductive layer 13A may be formed to have a thickness of approximately 100 to 400 Å. For example, the conductive layer 13A may be formed by depositing a tungsten layer to a thickness of approximately 200 Å using physical vapor deposition (PVD). To reduce parasitic capacitance between the substrate 11 and the conductive layer 13A, the buffer layer 12 may be formed of silicon oxide. For example, the buffer layer 12 may include Tetra Ethyl Ortho Silicate (TEOS).

A barrier material layer 14A may be formed over the conductive layer 13A. The barrier material layer 14A may include a metal-based material. The barrier material layer 14A may include a metal, a metal nitride, a metal silicide, or a combination thereof. The barrier material layer 14A may include titanium nitride, molybdenum, or ruthenium. The barrier material layer 14A may be formed by atomic layer deposition (ALD), physical vapor deposition (PVD), or chemical vapor deposition (CVD). The barrier material layer 14A may be formed to have a thickness of approximately 10 to 50 Å. For example, the barrier material layer 14A may be formed by depositing titanium nitride to a thickness of approximately 20 Å through physical vapor deposition (PVD).

A first oxide semiconductor stack 15A may be formed over the barrier material layer 14A. The first oxide semiconductor stack 15A may include a stack of a lower interface layer, a channel layer, and an upper interface layer, as illustrated in FIGS. 3A and 3B.

The first oxide semiconductor stack 15A may include a conductive material. The first oxide semiconductor stack 15A may include an oxide semiconductor material. The first oxide semiconductor stack 15A may include an indium-rich oxide semiconductor material, IGZO, or a combination thereof. For example, the first oxide semiconductor stack 15A may include a first indium-rich IGZO, IGZO, and second indium-rich IGZO that are stacked in the method order.

Subsequently, a first sacrificial layer 16A may be formed over the first oxide semiconductor stack 15A. The first sacrificial layer 16A may include silicon nitride. The first sacrificial layer 16A may include a stack of different materials.

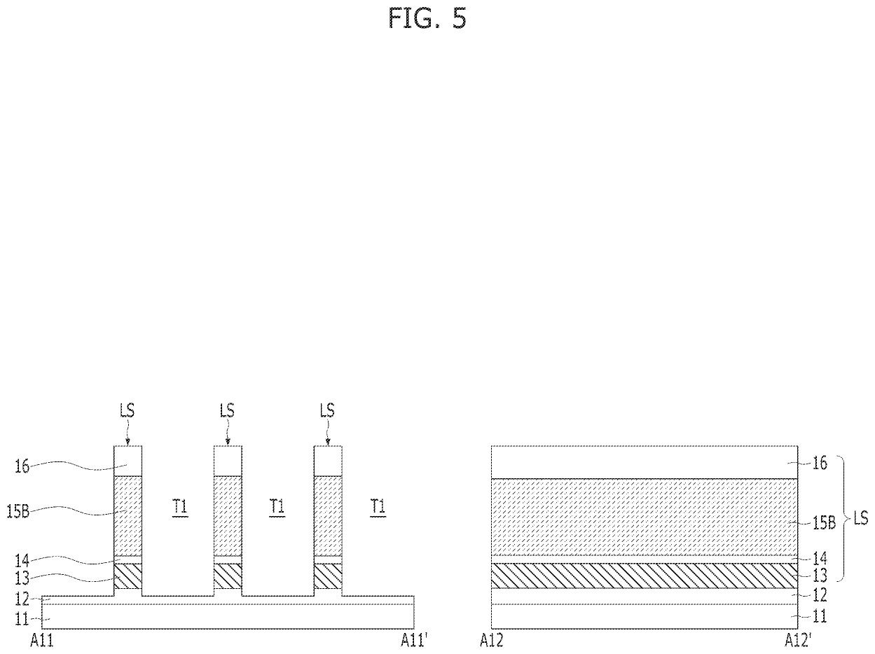

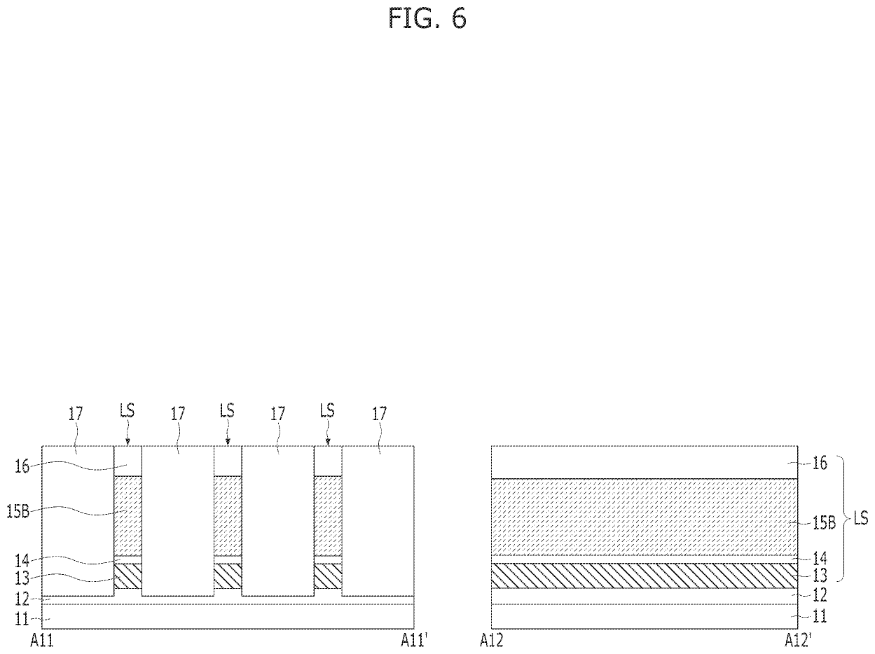

Referring now to FIG. 5, first sacrificial lines 16 may be formed over the first oxide semiconductor stack 15A. The first sacrificial lines 16 may be formed by etching the first sacrificial layer 16A. The first sacrificial lines 16 may serve to protect the first oxide semiconductor stack 15A from the subsequent processes. For example, the first sacrificial lines 16 may be used as an etch barrier during an etching process of the first oxide semiconductor stack 15A.

The first sacrificial lines 16 may include silicon nitride. The etching process of the first sacrificial layer 16A for forming the first sacrificial lines 16 may include a double patterning process. Each of the first sacrificial lines 16 may include a stack of different materials.

Subsequently, the first oxide semiconductor stack 15A may be etched using the first sacrificial lines 16 as an etch barrier, and then the barrier material layer 14A and the conductive layer 13A may be etched.

A plurality of line structures LS and first trenches T1 may be formed over the buffer layer 12 through a series of the etching processes described above. Each of the line structures LS may include a stack of a bit line 13, a bit line barrier layer 14, an oxide semiconductor line 15B, and a sacrificial line 16. The bit line barrier layer 14 may be formed by etching the barrier material layer 14A, and the bit line 13 may be formed by etching the conductive layer 13A. The oxide semiconductor line 15B may be formed by etching the oxide semiconductor stack 15A. The first trenches T1 may be disposed between the line structures LS.

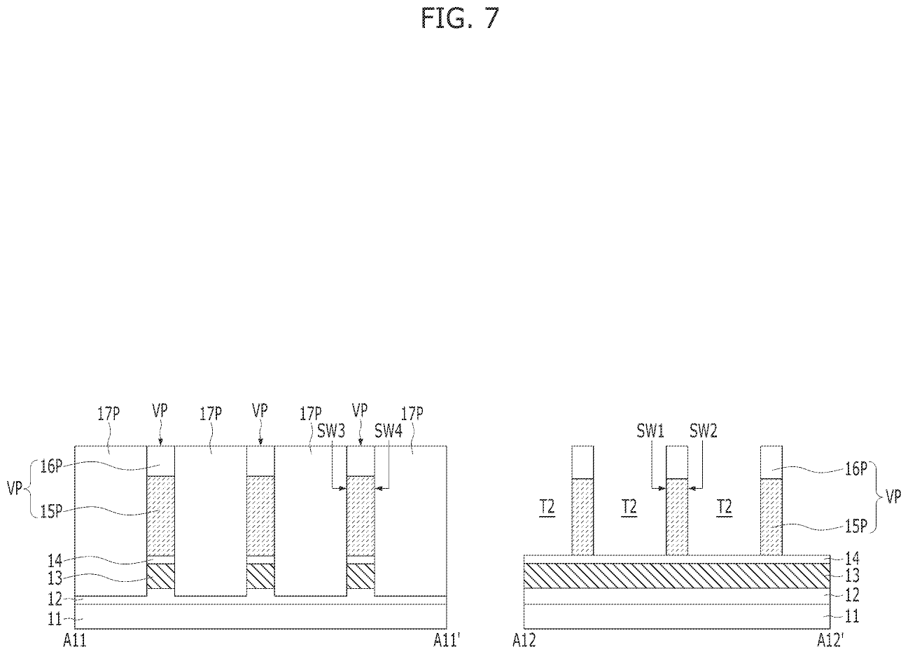

Referring to FIG. 6, first dielectric lines 17 may be formed between the line structures LS. The first dielectric lines 17 may include a dielectric material. For example, the first dielectric lines 17 may include silicon oxide, silicon nitride, silicon carbon oxide (SiCO), a spin-on-dielectric layer, or a combination thereof. After a dielectric material is deposited to fill the first trenches T1 between the line structures LS to form the first dielectric lines 17, a planarization process of a dielectric material may be performed. The first dielectric lines 17 may respectively fill the first trenches T1. To form the first dielectric lines 17, silicon nitride, silicon carbon oxide, and a spin-on dielectric layer may be sequentially formed and then a planarization process may be performed.

Referring to FIG. 7, portions of the line structures LS may be selectively etched to form first pillar structures VP. The first pillar structures VP may include a stack of first oxide semiconductor pillars 15P and first sacrificial pillars 16P. A bit line barrier layer 14 and a bit line 13 may be disposed below the first oxide semiconductor pillars 15P. The first sacrificial pillars 16P may be formed over the first oxide semiconductor pillars 15P.

In the A12-A12′ direction, second trenches T2 may be formed between the first oxide semiconductor pillars 15P. The lower surfaces of the second trenches T2 may expose the upper surface of the bit line barrier layer 14. The first trenches T1 and the second trenches T2 may intersect with each other. The first trenches T1 may be deeper than the second trenches T2. In the A11-A11′ direction, the dielectric lines 17 may be cut by the second trenches T2. Hereinafter, the first dielectric lines 17 may be simply referred to as ‘first dielectric pillars 17P’. The first dielectric pillars 17P may be disposed between the first oxide semiconductor pillars 21P in the A11-A11′ direction.

Each of the first oxide semiconductor pillars 15P may include first to fourth sidewalls SW1 to SW4. The first sidewall SW1 and the second sidewall SW2 of each of the first oxide semiconductor pillars 15P may be exposed by the second trenches T2, and the third sidewall SW3 and the fourth sidewall SW4 of each of the first oxide semiconductor pillars 15P may not be exposed by the dielectric pillars 17P. The first sacrificial pillar 16P may also include exposed sidewalls and non-exposed sidewalls in the same manner as the first oxide semiconductor pillars 15P.

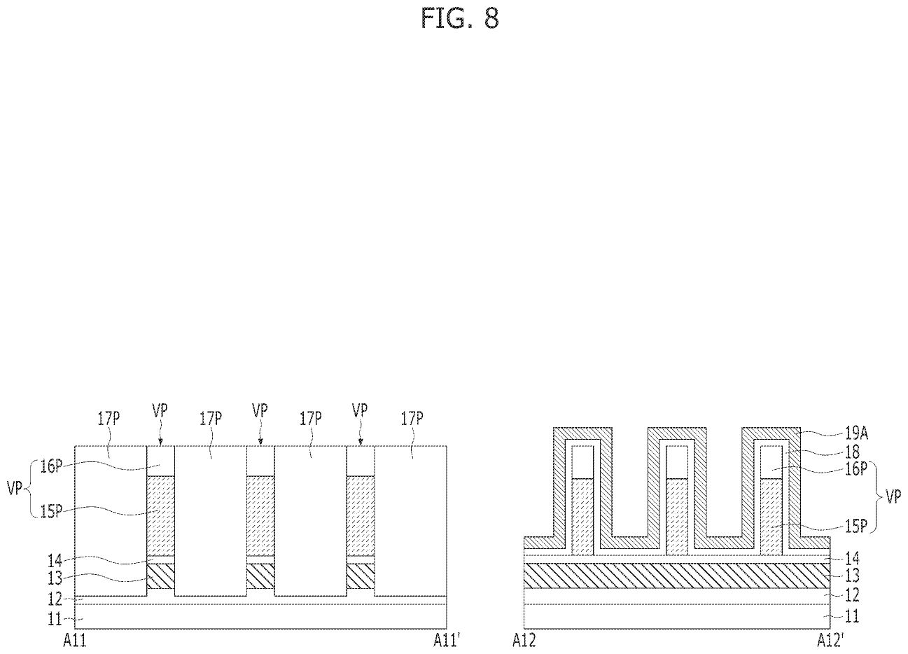

Referring to FIG. 8, a first gate dielectric layer 18 may be formed over the first pillar structures VP. The first gate dielectric layer 18 may be formed over the exposed first and second sidewalls SW1 and SW2 of the first oxide semiconductor pillars 15P. The first gate dielectric layer 18 may include silicon oxide, silicon nitride, silicon oxynitride, a high-k material, or a combination thereof. The high-k material may include a material having a dielectric constant which is greater than that of silicon oxide. For example, the high-k material may include a material having a dielectric constant which is greater than approximately 3.9. For another example, the high-k material may include a material having a dielectric constant which is greater than 10. For yet another example, the high-k material may include a material having a dielectric constant of approximately 10 to 30. The high-k material may include at least one metallic element. The high-k material may include hafnium-containing materials. The hafnium-containing materials may include hafnium oxide, hafnium silicon oxide, hafnium silicon oxynitride, or combinations thereof. According to another embodiment of the present invention, the high-k material may include lanthanum oxide, lanthanum aluminum oxide, zirconium oxide, zirconium silicon oxide, zirconium silicon oxynitride, aluminum oxide, or a combination thereof. As to the high-k material, other known high-k materials may selectively be used. The first gate dielectric layer 18 may include a metal oxide. The first gate dielectric layer 18 may be formed conformally over the first and second sidewalls SW1 and SW2 of the first oxide semiconductor pillars 15P. The first gate dielectric layer 18 may conformally cover the exposed sidewalls and upper surfaces of the first sacrificial pillars 16P.

A gate conductive layer 19A may be formed over the first gate dielectric layer 18. The gate conductive layer 19A may be formed conformally over the first gate dielectric layer 18. The gate conductive layer 19A may include a metal-based material. The gate conductive layer 19A may include a metal, a metal nitride, or a combination thereof. The gate conductive layer 19A may include tantalum nitride (TaN), titanium nitride (TiN), tungsten (W), tungsten nitride (WN), or a combination thereof.

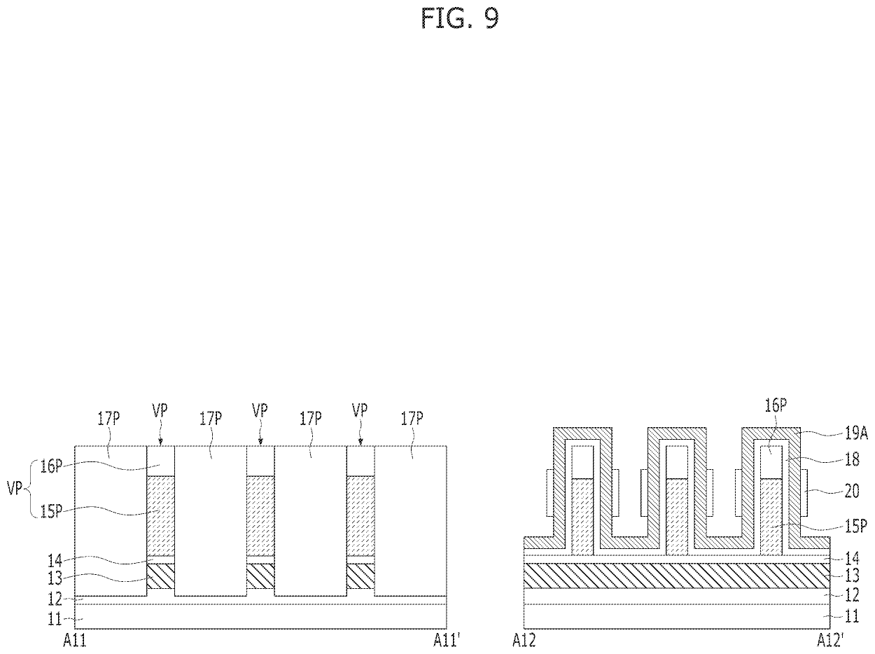

Referring to FIG. 9, sacrificial spacers 20 may be formed over the gate conductive layer 19A. The sacrificial spacers 20 may include an oxide. To form the sacrificial spacers 20, silicon oxide may be deposited over the gate conductive layer 19A, and then an etch-back process may be performed. The upper surfaces of the sacrificial spacers 20 may be disposed at a lower level than the upper surfaces of the sacrificial pillars 16P. The lower surfaces of the sacrificial spacers 20 may be disposed at a higher level than the lower surfaces of the sacrificial pillars 16P.

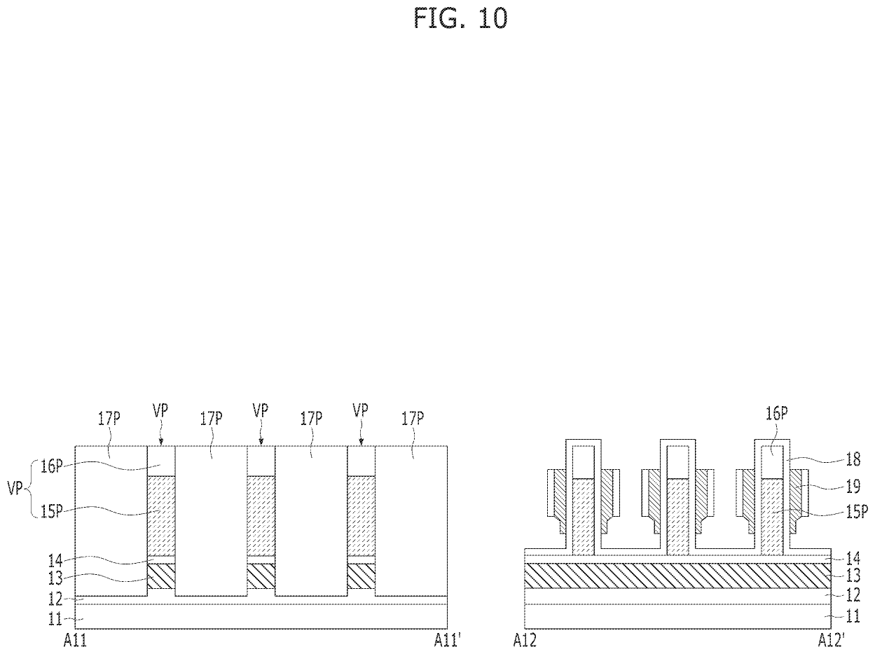

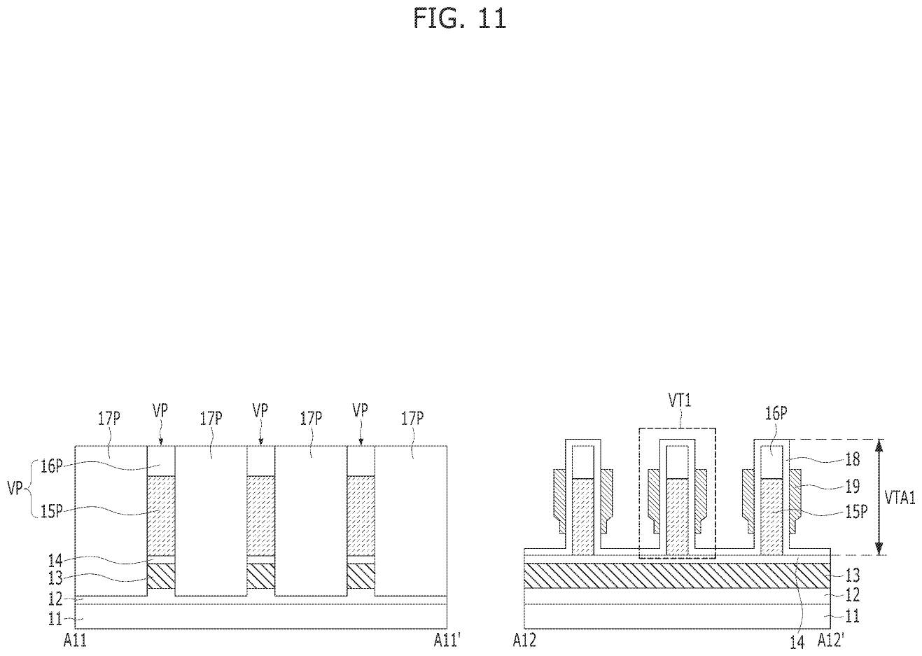

Referring to FIG. 10, first vertical gates 19 may be formed. To form the first vertical gates 19, the gate conductive layer 19A may be selectively etched using the sacrificial spacers 20 as an etch barrier. The sacrificial spacers 20 may serve to protect the first vertical gates 19 during the etching process of the gate conductive layer 19A. The process of etching the gate conductive layer 19A may include an etch-back process and a wet etching process that are performed sequentially. The non-tapered shape of the first vertical gates 19 may be formed as a result of the etch-back process, and the tapered shape of the first vertical gates 19 may be formed as a result of the subsequent wet etching process. The bottom portions of the first vertical gates 19 may become thin as a result of the wet etching process. The first vertical gates 19 may correspond to the first vertical gate 122 shown in FIG. 3A, and the bottom portion of the first vertical gates 19 may correspond to the first lower level portion 122L also shown in FIG. 3A.

Referring to FIG. 11, the sacrificial spacers 20 may be removed. Each of the first vertical gates 19 has a double structure and may be formed on each of the first and second sidewalls of the first oxide semiconductor pillars 15P. As illustrated in FIG. 2A, the first vertical gates 19 may extend in the second direction D2 and the bit lines 13 may extend in the first direction D1. The first oxide semiconductor pillars 15P and the first dielectric pillars 17P may be alternately disposed in the second direction D2, and the first vertical gates 19 may extend along the exposed sidewalls of the first oxide semiconductor pillars 15P and the first dielectric pillars 17P.

Through a series of the processes described above, the first vertical transistor array VTA1 may be formed. The first vertical transistor array VTA1 may include a plurality of first vertical transistors VT1.

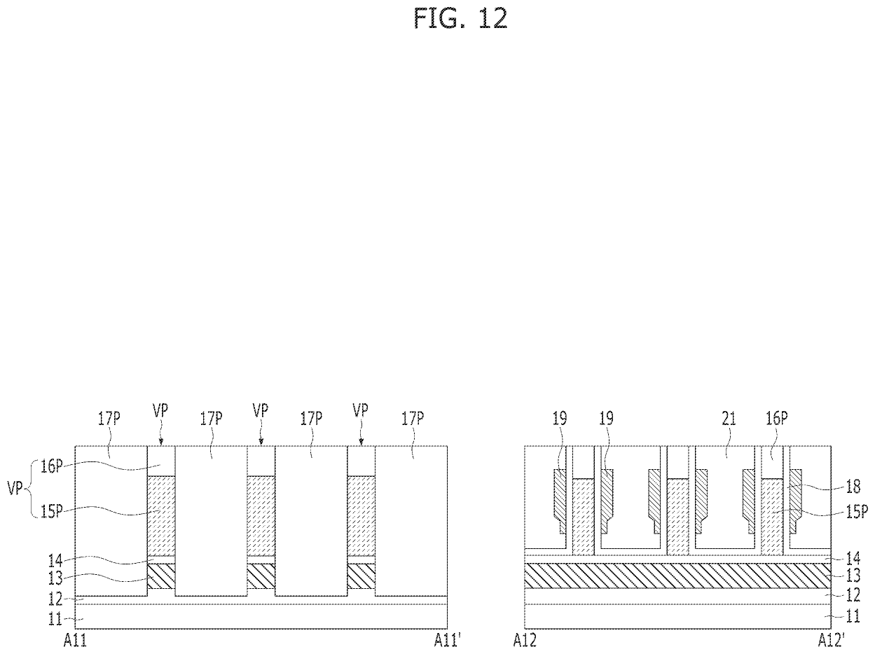

Referring to FIG. 12, a first inter-layer dielectric layer 21 may be formed over the first vertical gates 19. The first inter-layer dielectric layer 21 may be planarized to expose the upper surfaces of the first sacrificial pillars 16P. The first inter-layer dielectric layer 21 may include silicon oxide, such as a spin-on-dielectric (SOD) layer. The first sacrificial pillars 16P may serve as a stop layer during the planarization process of the first inter-layer dielectric layer 21.

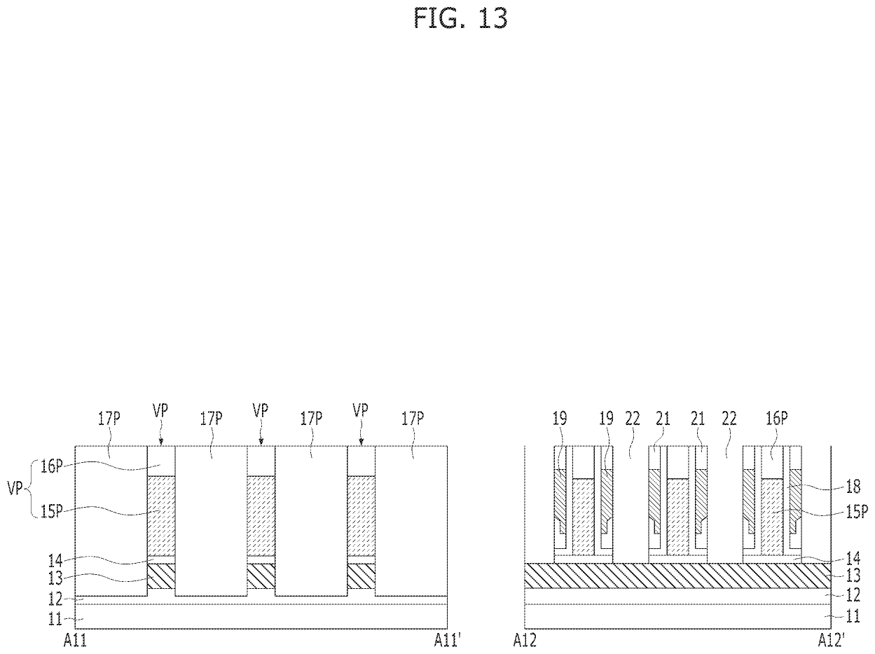

Referring to FIG. 13, first contact holes 22 may be formed by selectively etching portions of the first inter-layer dielectric layer 21. The first contact holes 22 may be formed to be self-aligned on the sidewalls of the first vertical gates 19. The first contact holes 22 may be expanded by etching the bit line barrier layer 14 below the first contact holes 22. The first contact holes 22 may expose the surface of the bit line 13.

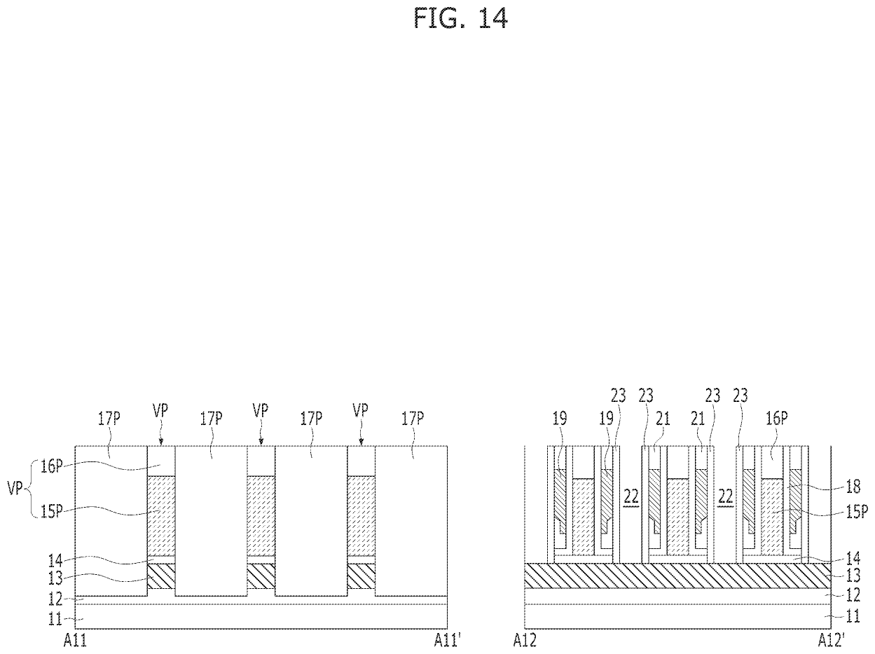

Referring to FIG. 14, first contact spacers 23 may be formed on the sidewalls of the first contact holes 22. The first contact spacers 23 may include a dielectric material. The first contact spacers 23 may include silicon oxide, silicon nitride, or a combination thereof. The first contact spacers 23 may expose the surface of the bit line 13.

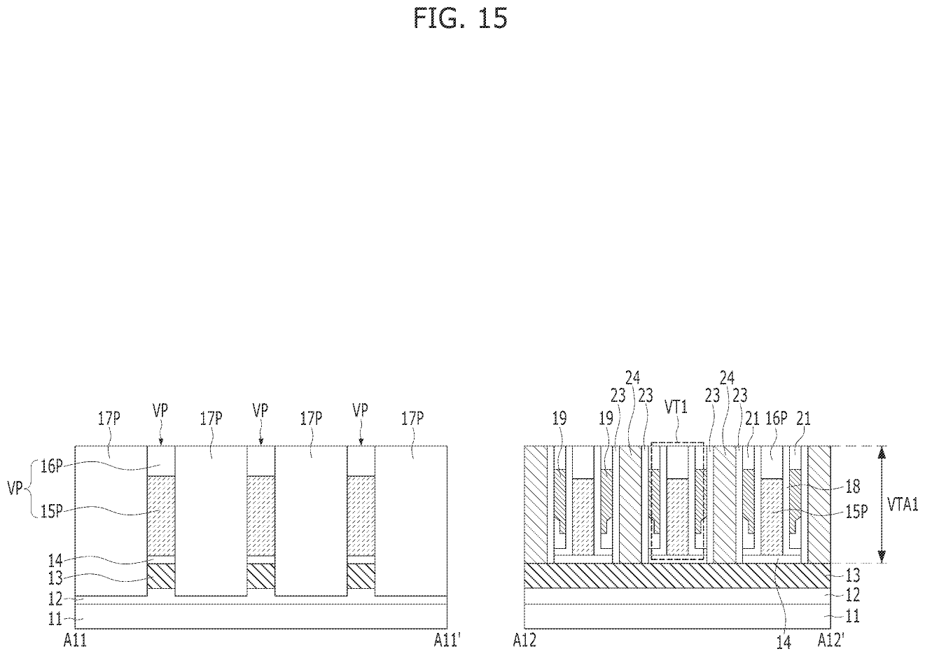

Referring to FIG. 15, first cell contact plugs 24 may be formed to fill the first contact holes 22. The first cell contact plugs 24 may be electrically connected to the bit line 13. The first cell contact plugs 24 may extend vertically from the surface of the bit line 13.

As described above, first cell contact plugs 24 may be disposed between the neighboring first vertical transistors VT1. The first cell contact plugs 24 may be disposed between the neighboring first vertical gates 19.

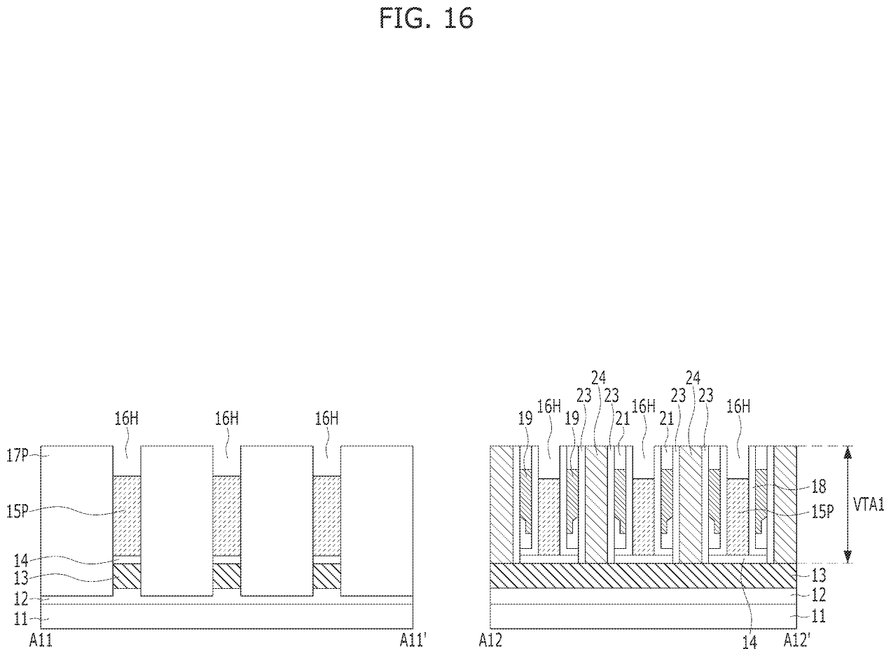

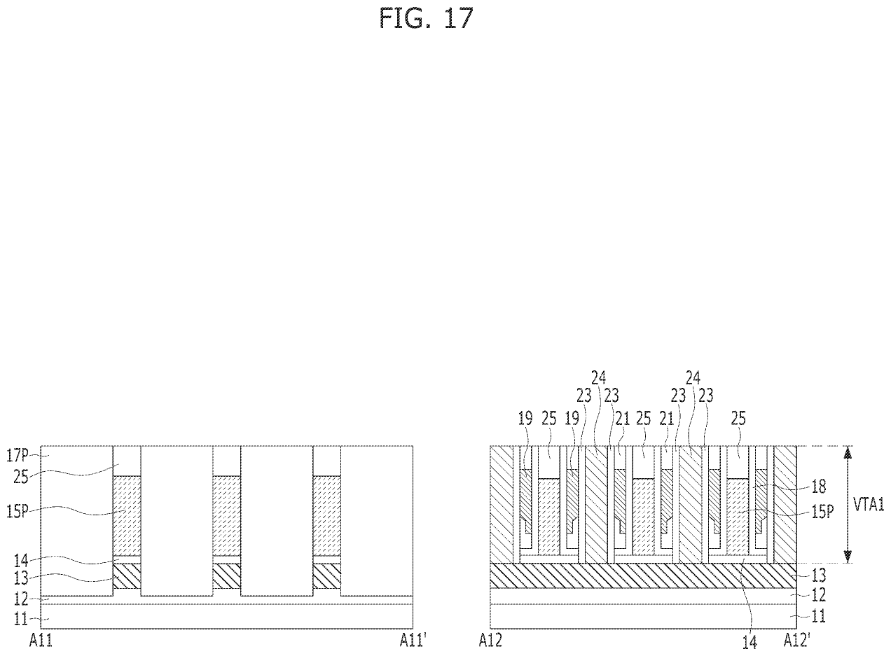

Referring to FIG. 16, the first sacrificial pillars 16P may be selectively removed. As a result, first hole-type recesses 16H may be formed. The first hole-type recesses 16H may selectively expose the upper surfaces of the first oxide semiconductor pillars 15P. The first sacrificial pillars 16P may be removed by a wet etching process.

Referring to FIG. 17, first pillar pads 25 may be formed to fill the first hole-type recesses 16H. The first pillar pads 25 may directly contact the first oxide semiconductor pillars 15P. The first pillar pads 25 may be formed of a material including a metal, a metal nitride, or a combination thereof. For example, the first pillar pads 25 may be formed by first depositing titanium nitride to fill the first hole-type recesses 16H and then planarizing the titanium nitride to expose the surfaces of the first cell contact plugs 24.

The first vertical transistor array VTA1 may further include first cell contact plugs 24 and first pillar pads 25.

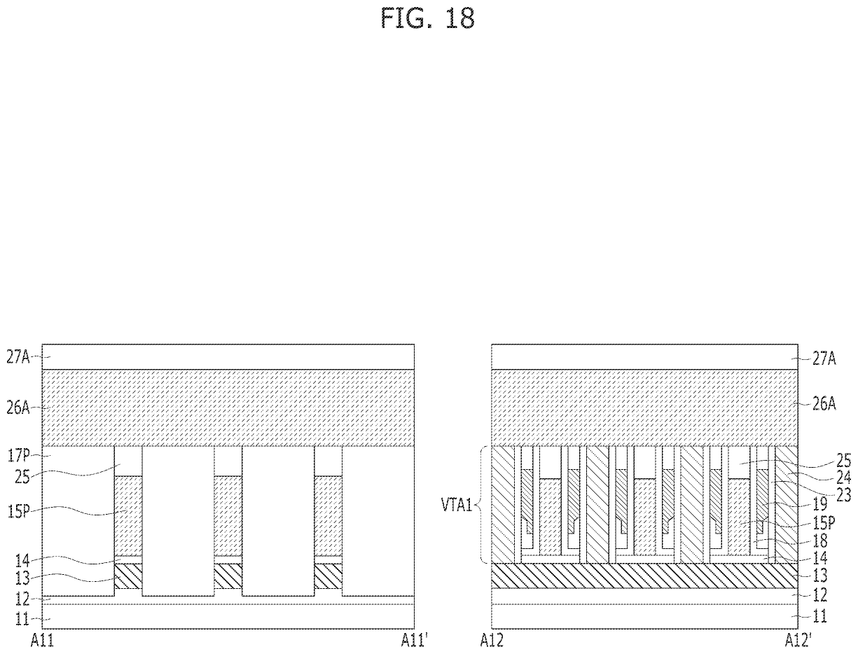

Referring to FIG. 18, a second oxide semiconductor stack 26A may be formed over the first vertical transistor array VTA1 and the first cell contact plugs 24. A second sacrificial layer 27A may be formed over the second oxide semiconductor stack 26A. The second oxide semiconductor stack 26A may be identical to the first oxide semiconductor stack 15A. The second sacrificial layer 27A may be identical to the first sacrificial layer 16A.

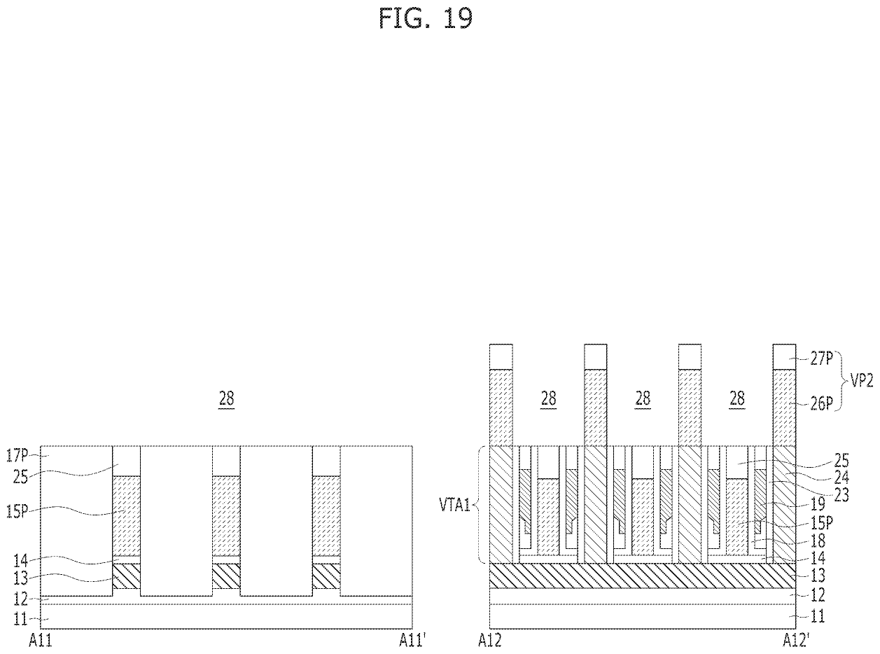

Subsequently, a series of the processes illustrated in FIGS. 5 to 7 may be performed. As a result, as illustrated in FIG. 19, a stack of second pillar structures VP2, that is, second oxide semiconductor pillars 26P, and second sacrificial pillars 27P, may be formed. A third trench 28 may be formed between adjacent second pillar structures VP2.

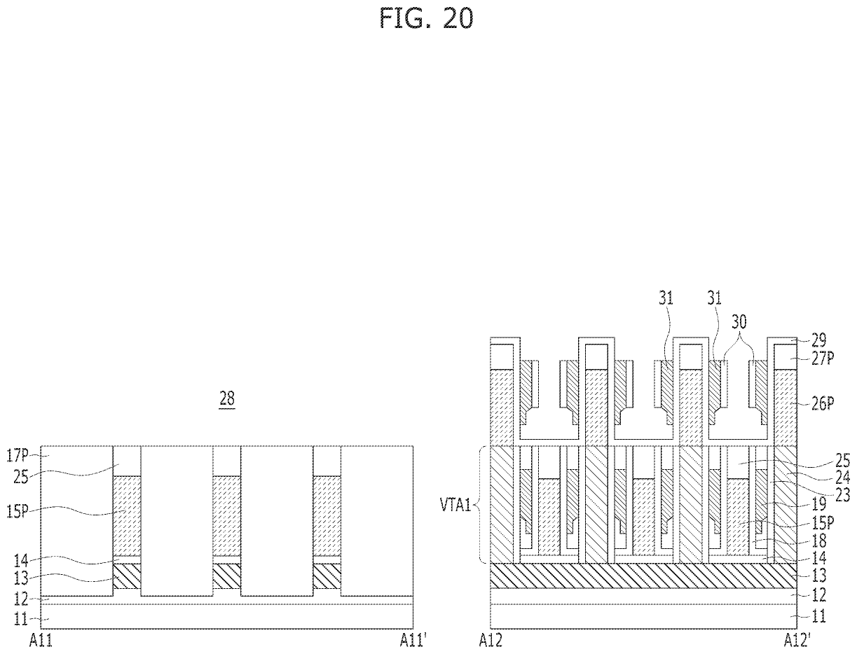

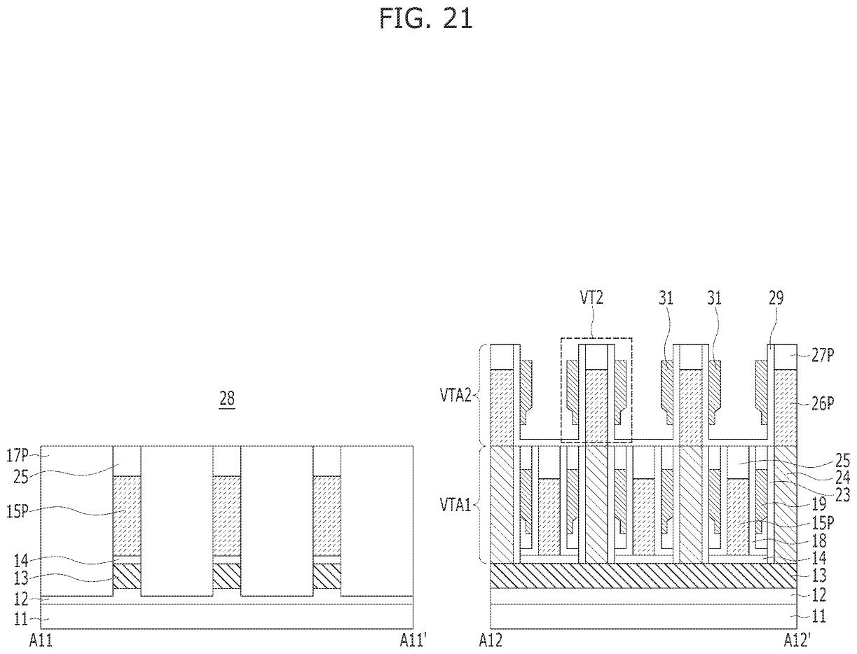

Subsequently, a series of the processes illustrated in FIGS. 8 to 11 may be performed to form the second gate dielectric layer 29 over the second pillar structures VP2, as illustrated in FIG. 20, and to form second vertical gates 31 by using sacrificial spacers 30. The second gate dielectric layer 29 may include silicon oxide, silicon nitride, silicon oxynitride, a high-k material, or a combination thereof.

The second vertical gates 31 may correspond to the second vertical gates 132 shown in FIG. 3B.

Referring to FIG. 21, the sacrificial spacers 30 may be removed. Each of the second vertical gates 31 may have a double structure and may be formed on the sidewalls of the second oxide semiconductor pillars 26P. As illustrated in FIG. 2B, the second vertical gates 31 may extend in the second direction D2, and the bit lines 13 may extend in the first direction D1. The second oxide semiconductor pillars 26P may be disposed in the second direction D2.

Through a series of the processes described above, the second vertical transistor array VTA2 may be formed. The second vertical transistor array VTA2 may include a plurality of second vertical transistors VT2. The second oxide semiconductor pillars 26P and the first cell contact plugs 24 may be electrically connected to each other.

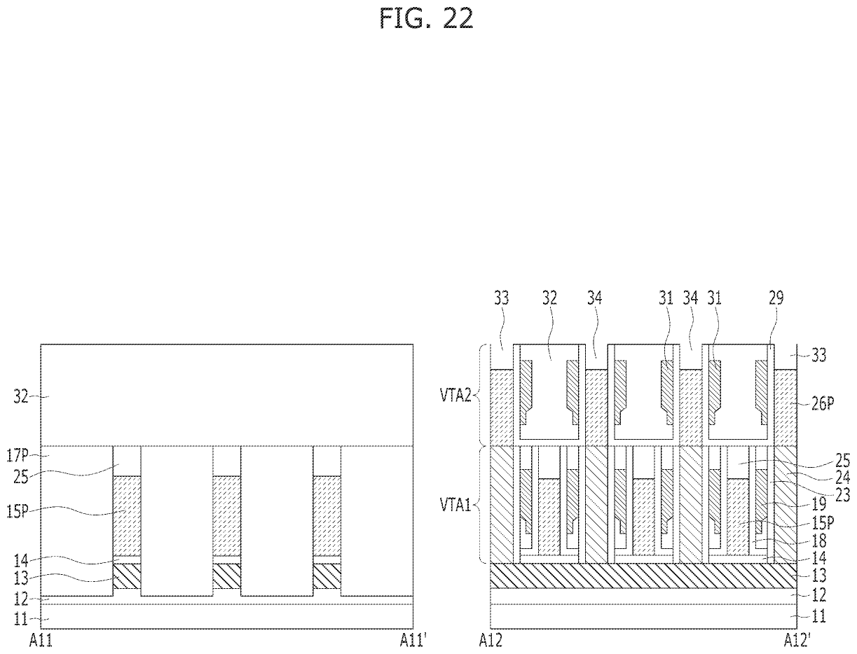

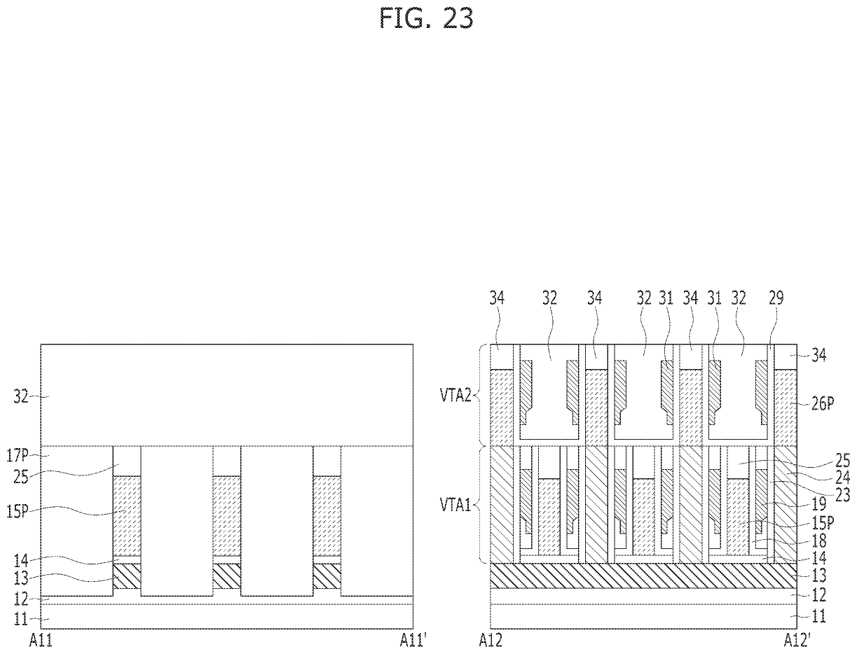

Referring to FIG. 22, second inter-layer dielectric layers 32 may be formed between the second vertical transistors VT2. The second inter-layer dielectric layers 32 may be disposed between the second vertical gates 31.

Subsequently, the second sacrificial pillars 27P may be selectively removed. As a result, second hole-type recesses 33 may be formed. The second hole-type recesses 33 may selectively expose the upper surfaces of the second oxide semiconductor pillars 26P. The second sacrificial pillars 27P may be removed by a wet etching process.

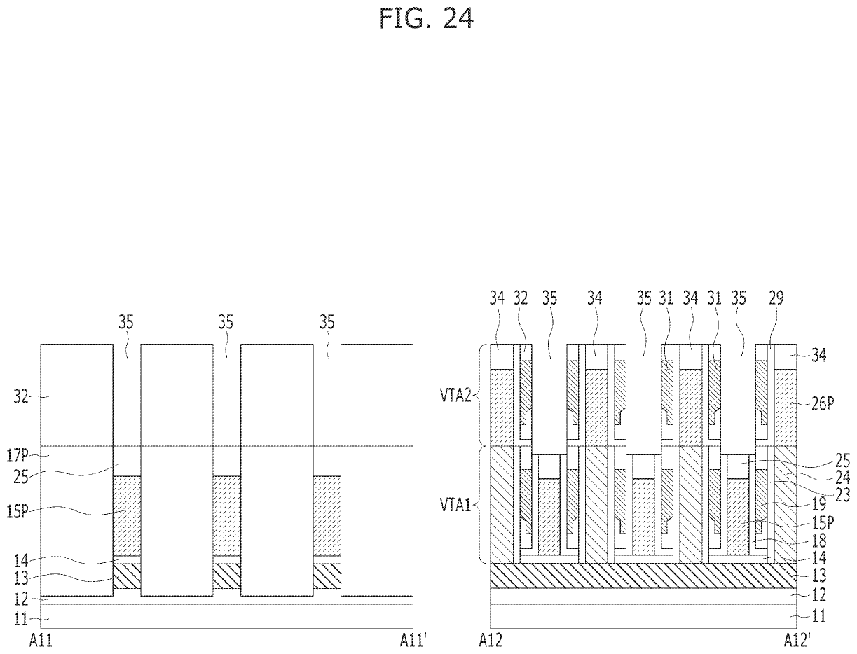

Referring to FIG. 23, second pillar pads 34 may be formed to fill the second hole-type recesses 33 and directly contact the second oxide semiconductor pillars 26P. The second pillar pads 34 may include a metal, a metal nitride, or a combination thereof. For example, the second pillar pads 34 may be formed by first depositing titanium nitride to fill the second hole-type recesses 33, and then planarizing the titanium nitride to expose the surfaces of the second inter-layer dielectric layers 32.

Referring to FIG. 24, second contact holes 35 may be formed by selectively etching portions of the second inter-layer dielectric layer 32. The second contact holes 35 may be formed to be self-aligned to the sidewalls of the second vertical gates 31. The second contact holes 35 may be expanded by etching the lower surfaces of the second gate dielectric layers 29 below the second contact holes 35. The second contact holes 35 may expose the surfaces of the first pillar pads 25.

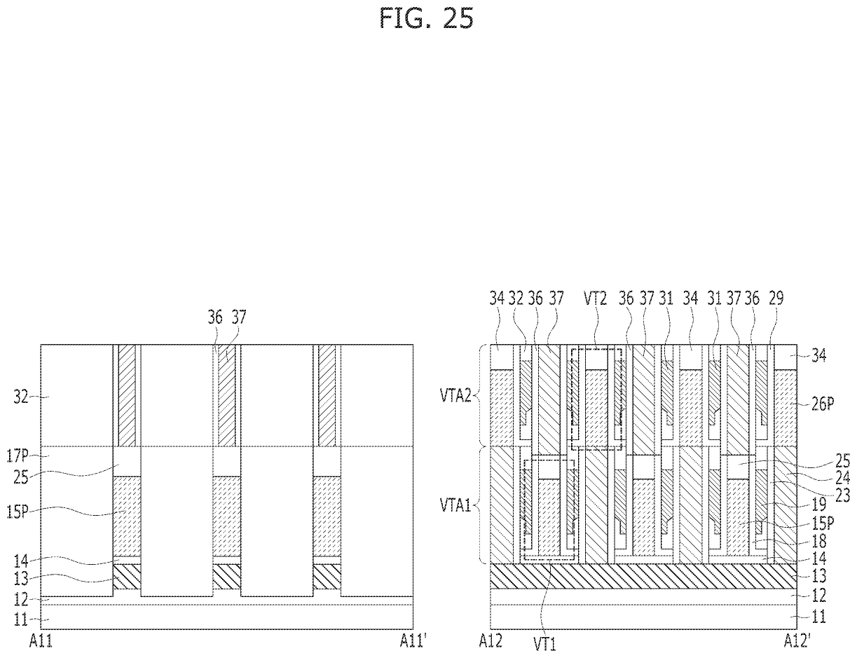

Referring to FIG. 25, second contact spacers 36 may be formed on the sidewalls of the second contact holes 35. The second contact spacers 36 may include a dielectric material. The second contact spacers 36 may include silicon oxide, silicon nitride, or a combination thereof. The second contact spacers 36 may expose the surfaces of the first pillar pads 25.

Subsequently, second cell contact plugs 37 may be formed to fill the second contact holes 35 as shown in FIG. 25. The second cell contact plugs 37 may be electrically connected to the first pillar pads 25. The second cell contact plugs 37 may extend vertically from the surfaces of the first pillar pads 25.

The second vertical transistor array VTA2 may further include second cell contact plugs 37 and second pillar pads 34.

As described above, the first vertical transistor array VTA1 may be disposed over the bit line 13, and the second vertical transistor array VTA2 may be disposed over the first vertical transistor array VTA1. The first cell contact plugs 24 may be disposed between the neighboring first vertical transistors VT1. The first vertical transistors VT1 and the first cell contact plugs 24 may be alternately arranged in the direction A12-A12′ that the bit line 13 extends. The second cell contact plugs 37 may be disposed between the neighboring second vertical transistors VT2. The second vertical transistors VT2 and the second cell contact plugs 37 may be alternately arranged in the direction A12-A12′ that the bit line 13 extends. The first cell contact plugs 24 may be electrically connected to the second oxide semiconductor pillars 26, and the second cell contact plugs 37 may be electrically connected to the first oxide semiconductor pillars 15P.

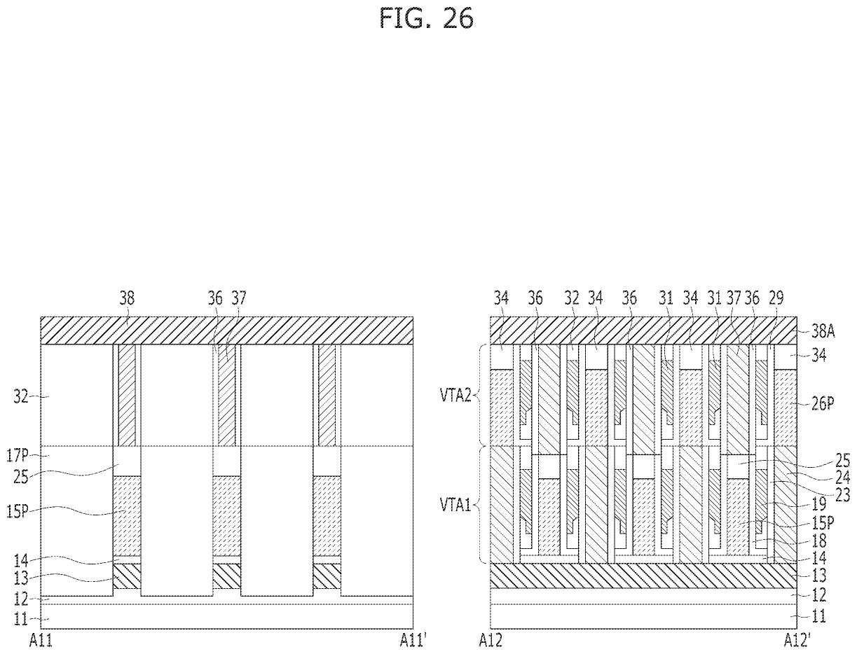

Referring to FIG. 26, a pad material layer 38A may be formed over the second vertical transistor array VTA2 and the second cell contact plugs 37. The pad material layer 38A may include a metal-based material, a semiconductor material, or a combination thereof.

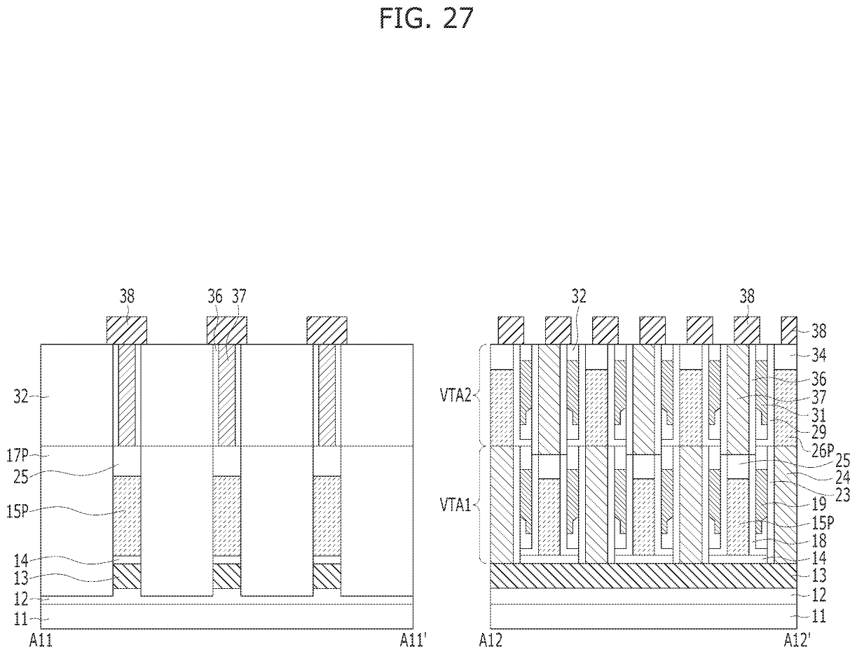

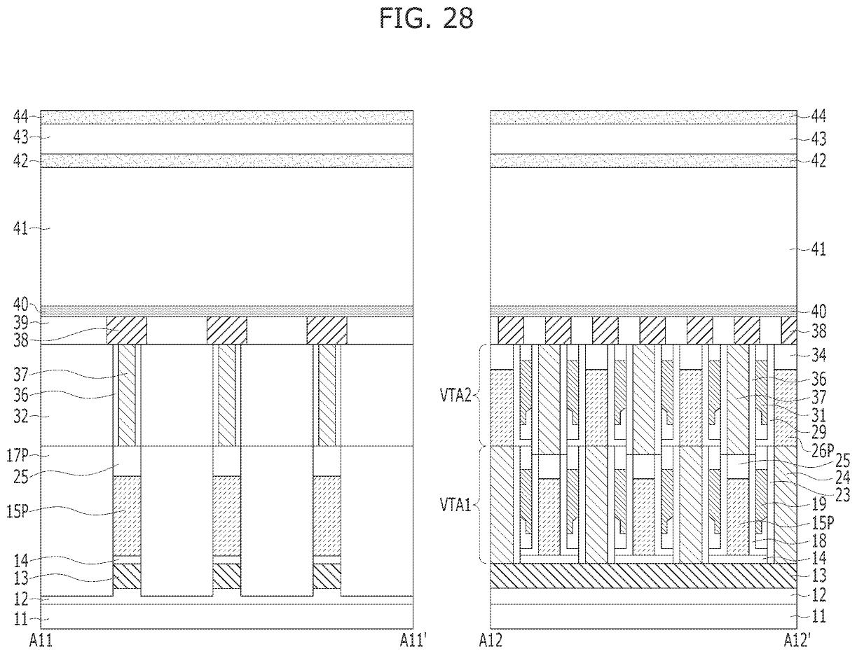

Referring to FIG. 27, landing pads 38 may be formed by etching the pad material layer 38A. The landing pads 38 may be coupled to the second cell contact plugs 37 and the second pillar pads 34, respectively.

According to another embodiment of the present invention, the second cell contact plugs 37 and the landing pads 38 may be formed simultaneously.

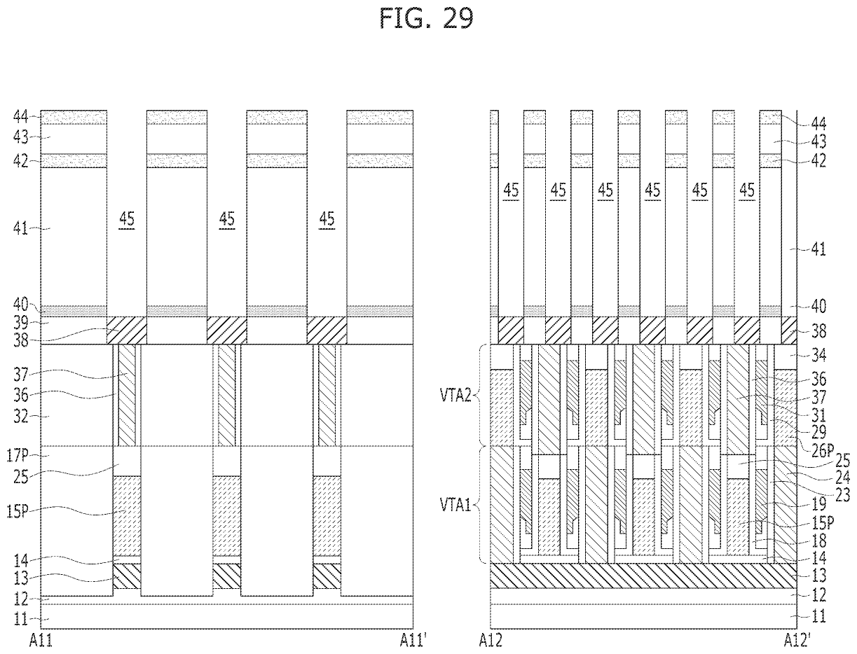

Referring to FIG. 28, after the pad dielectric layers 39 are formed to fill the space between the landing pads 38, an etch stop layer 40 may be formed over the pad dielectric layers 39 and the landing pads 38. A first mold layer 41, a first supporter layer 42, a second mold layer 43, and a second supporter layer 44 may be sequentially formed over the etch stop layer 40.

The etch stop layer 40 may be formed of a material having an etch selectivity with respect to the first mold layer 41. The etch stop layer 40 may include silicon nitride or silicon oxynitride. The first mold layer 41 may include a dielectric material. The first mold layer 41 may be silicon oxide (SiO₂). The first mold layer 41 may be formed to be thicker than the first supporter layer 42. The first mold layer 41 may be formed by a deposition process, such as chemical vapor deposition (CVD), atomic layer deposition (ALD), or physical vapor deposition (PVD). The first mold layer 41 may include phosphorus-doped silicon oxide or boron-doped silicon oxide. The first mold layer 41 may include USG, PSG, BSG, BPSG, FSG, or a combination thereof. The phosphorus-doped silicon oxide and the boron-doped silicon oxide may be easily removed in a subsequent process due to their quick etching rates with respect to an etching solution.

The first supporter layer 42 may be formed of a material having an etch selectivity with respect to the first mold layer 41 and the second mold layer 43. The first supporter layer 42 may include silicon nitride or silicon carbon nitride (SiCN).

The second mold layer 43 may include a dielectric material. The second mold layer 43 may be silicon oxide (SiO₂). The second mold layer 43 may be formed to be thicker than the first supporter layer 42. The second mold layer 43 may be formed by a deposition process, such as chemical vapor deposition (CVD), atomic layer deposition (ALD), or physical vapor deposition (PVD). The second mold layer 43 may include phosphorus-doped silicon oxide or boron-doped silicon oxide. The second mold layer 43 may include USG, PSG, BSG, BPSG, FSG, or a combination thereof. The first mold layer 41 and the second mold layer 43 may be the same material or different materials.

According to another embodiment of the present invention, the first mold layer 41 and the second mold layer 43 may be formed of a silicon material, such as amorphous silicon or polysilicon.

The second supporter layer 44 may be formed of a material having an etch selectivity with respect to the second mold layer 43. The second supporter layer 44 may include silicon nitride or silicon carbon nitride (SiCN).

The first supporter layer 42 and the second supporter layer 44 may be the same material or different materials. Both the first supporter layer 42 and the second supporter layer 44 may be formed of silicon nitride. According to another embodiment of the present invention, the first supporter layer 42 may be formed of silicon nitride, and the second supporter layer 44 may be formed of silicon carbon nitride. The second supporter layer 44 may be thicker than the first supporter layer 42.

According to another embodiment of the present invention, another supporter layer may be further formed. For example, the supporter structure may have a multi-level supporter layer structure.

Referring to FIG. 29, an opening 45 may be formed. To form the opening 45, the second supporter layer 44, the second mold layer 43, the first supporter layer 42, and the first mold layer 41 may be sequentially etched by using a mask layer (not shown) as an etch barrier. The etching process for forming the opening 45 may stop at the etch stop layer 40. The opening 45 may be formed by using a dry etching process, a wet etching process, or a combination thereof. The opening 45 may be referred to as a hole in which a lower electrode (or a storage node) is to be formed.

Subsequently, the etch stop layer 40 may be etched to expose the upper surfaces of the landing pads 38 below the opening 45.

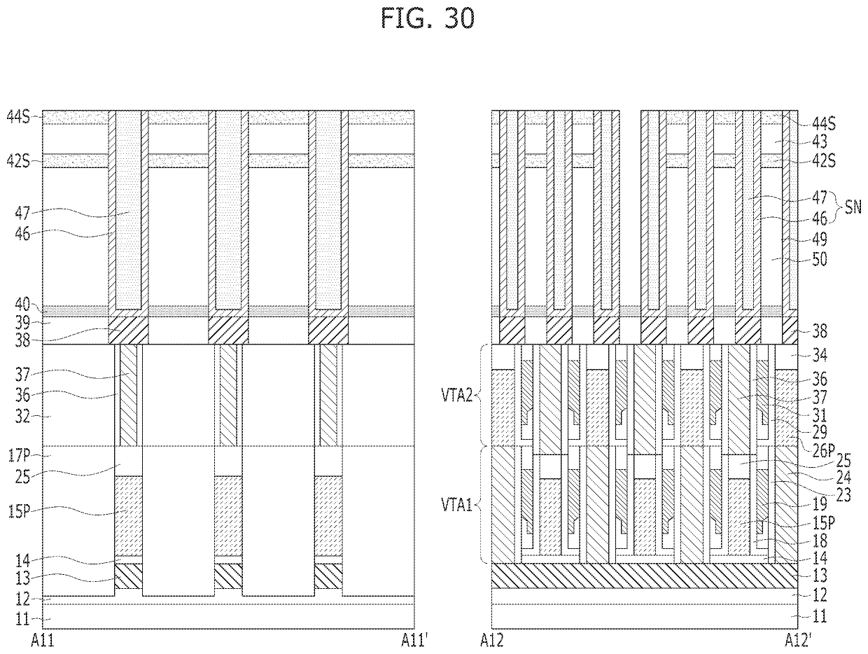

Referring to FIG. 30, a lower electrode SN may be formed in the opening 45. The lower electrode SN may fill the interior of the opening 45. The lower electrode SN may include polysilicon, a metal, a metal nitride, a conductive metal oxide, a metal silicide, a noble metal, or a combination thereof. The lower electrode SN may include at least one of titanium (Ti), titanium nitride (TiN), tantalum (Ta), tantalum nitride (TaN), titanium aluminum nitride (TiAlN), tungsten (W), tungsten nitride (WN), ruthenium (Ru), ruthenium oxide (RuO₂), iridium (Ir), iridium oxide (IrO₂), platinum (Pt), or a combination thereof. The lower electrode SN may include titanium nitride (TiN). The lower electrode SN may include titanium nitride (ALD-TiN) formed by atomic layer deposition (ALD). The lower electrode SN may include a stack of a cylinder-shape electrode 46 and a pillar-shaped electrode 47. According to another embodiment of the present invention, the lower electrode SN may include a hybrid structure of a titanium nitride cylinder and a polysilicon pillar.

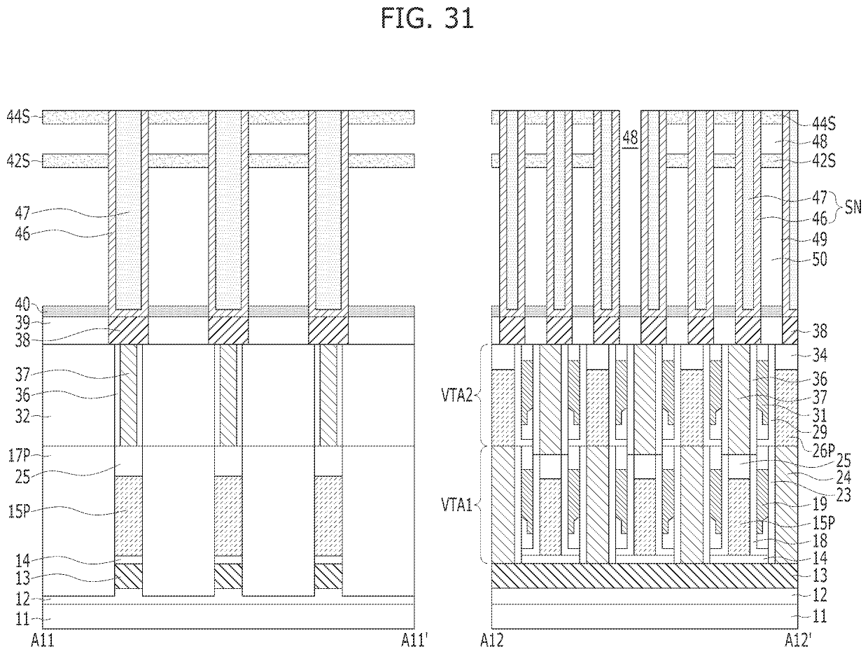

Referring to FIG. 31, the second supporter layer 44, the second mold layer 43, and the first supporter layer 42 may be sequentially etched. As a result, a supporter opening 48 exposing the first mold layer 41 may be formed, and an upper level supporter 44S and a lower level supporter 42S may be formed.

The upper level supporter 44S and the lower level supporter 42S may contact the outer wall of the lower electrode SN. The upper level supporter 44S and the lower level supporter 42S may prevent the lower electrodes SN from collapsing during the subsequent process of removing the second mold layer 43 and the first mold layer 41.

Subsequently, the second mold layer 43 and the first mold layer 41 may be removed through the supporter opening 48. The first and second mold layers 41 and 43 may be removed by a wet dip-out process. The wet dip-out process for removing the first and second mold layers 41 and 43 may be performed using an etching solution capable of selectively removing the first and second mold layers 41 and 43. When the first and second mold layers 41 and 43 contain silicon oxide, the first and second mold layers 41 and 43 may be removed by a wet etching process using hydrofluoric acid (HF).

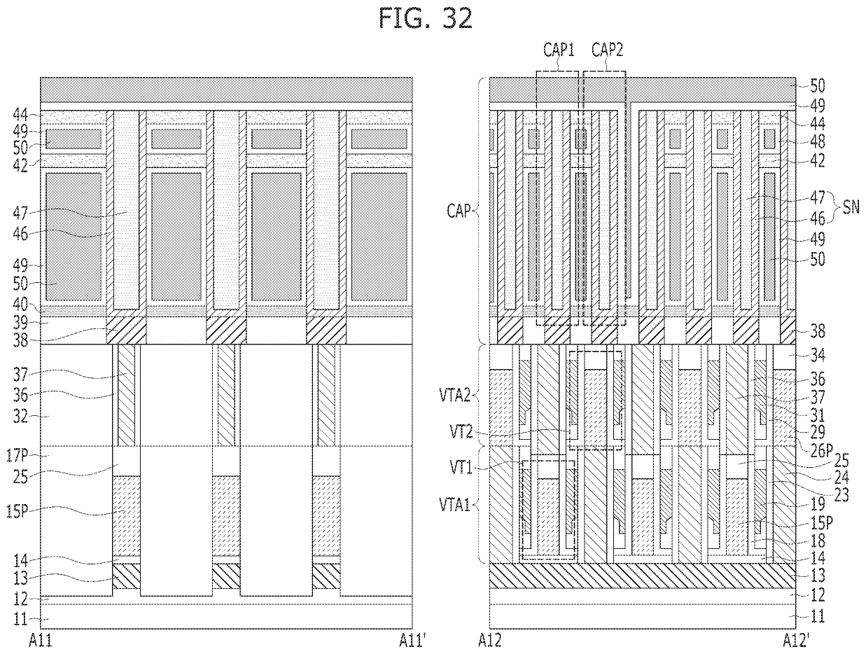

Referring to FIG. 32, a dielectric layer 49 may be formed over the lower electrode SN and the lower and upper level supporters 42S and 44S. The dielectric layer 49 may include a high-k material having a higher dielectric constant than silicon oxide. The high-k material may include hafnium oxide (HfO₂), zirconium oxide (ZrO₂), aluminum oxide (Al₂O₃), titanium oxide (TiO₂), tantalum oxide (Ta₂O₅), niobium oxide (Nb₂O₅) or strontium titanium oxide (SrTiO₃). According to another embodiment of the present invention, the dielectric layer 49 may be formed of a composite layer including two or more layers of the previously mentioned high-k materials. According to this embodiment of the present invention, the dielectric layer 49 may be formed of a zirconium oxide-based material that has excellent leakage current characteristics while sufficiently reducing an equivalent oxide thickness (EOT). For example, it may include a ZAZ (ZrO₂/Al₂O₃/ZrO₂) stack. According to another embodiment of the present invention, the dielectric layer 49 may include a TiO₂/ZrO₂/Al₂O₃/ZrO₂ stack, a TiO₂/HfO₂/Al₂O₃/HfO₂ stack, a Ta₂O₅/ZrO₂/Al₂O₃/ZrO₂ stack, or a Ta₂O₅/HfO₂/Al₂O₃/HfO₂ stack.

Subsequently, an upper electrode 50 may be formed over the dielectric layer 49. The upper electrode 50 may fill the space between the neighboring lower electrodes SN. The upper electrode 50 may extend to cover the upper portions of the lower electrodes SN. The upper electrode 50 may include a conductive material. The upper electrode 50 may include titanium nitride, silicon germanium, tungsten, tungsten nitride, or a combination thereof.

As described above, the first vertical transistor array VTA1 may be disposed over the bit line 13, and the second vertical transistor array VTA2 may be disposed over the first vertical transistor array VTA1. A capacitor array CAP may be disposed over the second vertical transistor array VTA2.

First cell contact plugs 24 may be disposed between the neighboring first vertical transistors VT1. The first vertical transistors VT1 and the first cell contact plugs 24 may be alternately arranged in the direction A12-A12′ that the bit line 13 extends. The second cell contact plugs 37 may be disposed between the neighboring second vertical transistors VT2. The second vertical transistors VT2 and the second cell contact plugs 37 may be alternately arranged in the direction A12-A12′ that the bit line 13 extends. The first cell contact plugs 24 may be electrically connected to the second oxide semiconductor pillars 26, and the second cell contact plugs 37 may be electrically connected to the first oxide semiconductor pillars 15P.

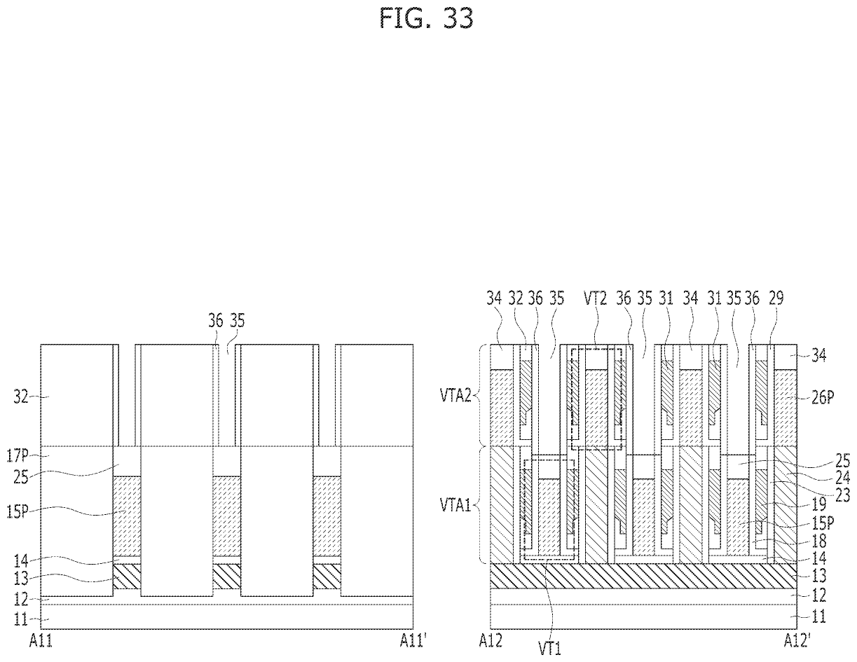

FIGS. 33 to 35 illustrate a method for fabricating a semiconductor device in accordance with another embodiment of the present invention. FIGS. 33 to 35 illustrate a method of simultaneously forming second cell contact plugs and landing pads.

The second contact holes 35 may be formed by performing a series of the processes illustrated in FIGS. 4 to 26.

Subsequently, referring to FIG. 33, second contact spacers 36 may be formed on the sidewalls of the second contact holes 35.

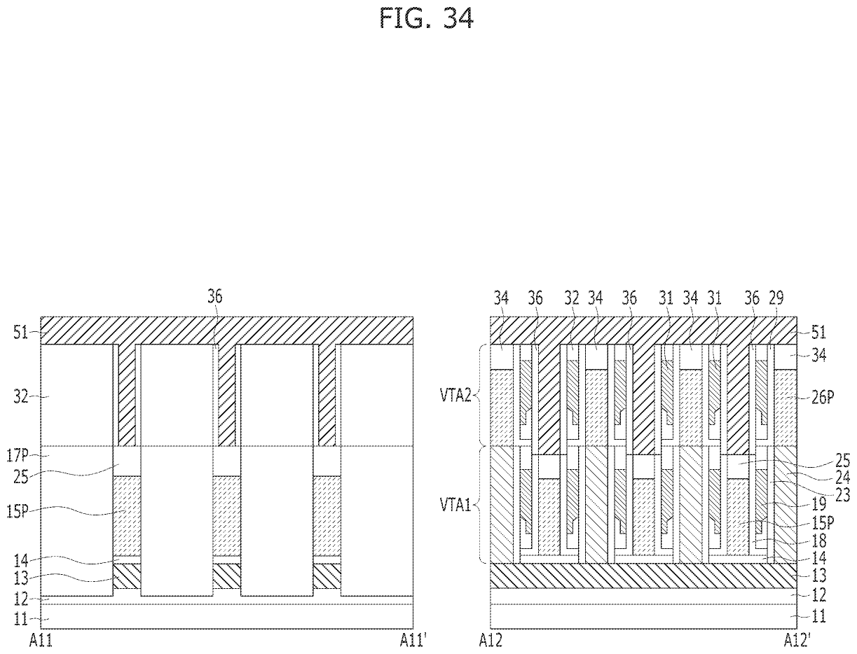

Referring to FIG. 34, a contact material 51 may be formed to fill the second contact holes 35. The contact material 51 may include a metal-based material.

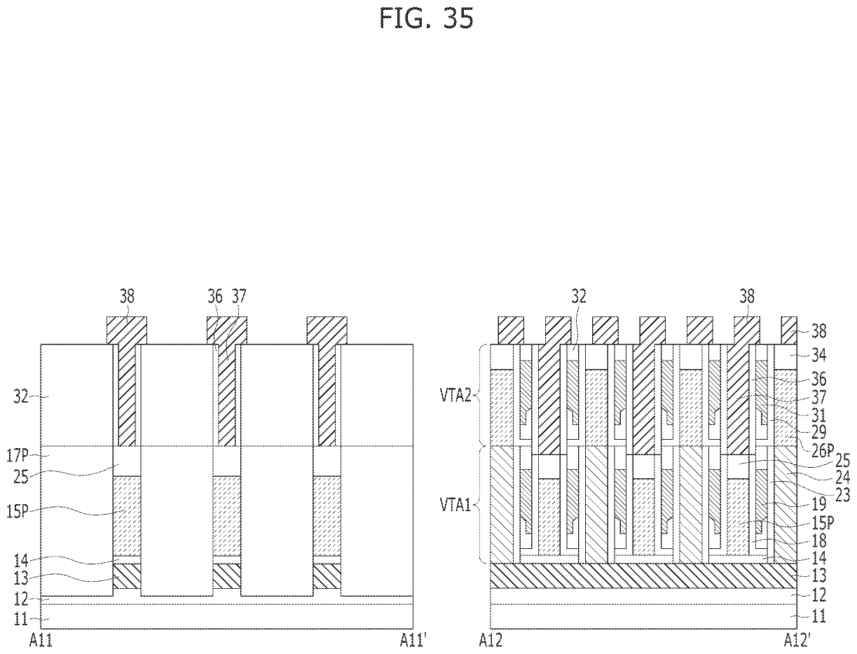

Referring to FIG. 35, the contact material 51 may be etched to simultaneously form the second cell contact plugs 37 and the landing pads 38.

Subsequently, a series of the processes illustrated in FIGS. 28 to 32 may be performed.

According to the above-described embodiments of the present invention, by disposing the first vertical transistors and the second vertical transistors in a two-layer structure, the area of a cell may be reduced without scaling the vertical transistors.

Accordingly, it is possible to reduce costs by increasing a net die without deteriorating cell performance.

Also, since the bit line and a transistor are formed sequentially by using a depositable channel material, process difficulty may be reduced.

Also, gate-induced drain leakage and junction leakage may be suppressed and thus retention characteristics may be improved by using a metal oxide, particularly IGZO, as a channel material.

According to an embodiment of the present invention, it is possible to reduce the cell area without scaling the vertical transistors by disposing vertical transistors in a multi-layer structure (e.g., two-layer structure).

Accordingly, it is possible to reduce costs by increasing a net die without deteriorating cell performance.

While the present invention has been described with respect to the specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A semiconductor device comprising:
a bit line;
a plurality of first semiconductor pillars disposed over the bit line;
a plurality of first cell contact plugs disposed between the first semiconductor pillars;
a plurality of second semiconductor pillars coupled to the first cell contact plugs;
a plurality of second cell contact plugs disposed between the second semiconductor pillars and coupled to the first semiconductor pillars; and
a plurality of capacitors respectively coupled to the second semiconductor pillars and the second cell contact plugs.

2. The semiconductor device of claim 1, further comprising:
a first vertical gate having a double structure disposed on both sidewalls of each of the first semiconductor pillars; and
a second vertical gate having a double structure disposed on both sidewalls of each of the second semiconductor pillars.

3. The semiconductor device of claim 2, wherein each of the first and second vertical gates has a tapered shape.

4. The semiconductor device of claim 2, wherein each of the first and second vertical gates includes
an upper level portion and
a lower level portion that is thinner than the upper level portion.

5. The semiconductor device of claim 1, wherein each of the first semiconductor pillars and the second semiconductor pillars includes
an oxide semiconductor material.

6. The semiconductor device of claim 5, wherein each of the first semiconductor pillars and the second semiconductor pillars includes:
a lower interface layer;
an upper interface layer; and
a channel layer between the lower interface layer and the upper interface layer.

7. The semiconductor device of claim 6, wherein the channel layer includes IGZO, IZTO or ZTO, and
the lower and upper interface layers include indium-rich IGZO, and
the indium-rich IGZO includes IGZO having an indium content greater than indium contents of gallium and zinc.

8. The semiconductor device of claim 1, wherein the bit line includes a metal material.

9. The semiconductor device of claim 1, further comprising:
a substrate disposed below the bit line, and
a buffer layer disposed between the bit line and the substrate.

10. The semiconductor device of claim 1, wherein each of the first and second semiconductor pillars includes IGZO, IZTO, ZTO, indium-rich IGZO, or a combination thereof.

11. The semiconductor device of claim 1,
wherein each of the capacitors includes a first electrode, a dielectric layer, and a second electrode,
wherein the first electrode includes a cylinder-shape electrode, and
wherein a pillar-shaped electrode is disposed inside the cylinder-shape electrode.

12. The semiconductor device of claim 11, wherein the capacitors further include a multi-layer level supporter supporting outer walls of the first electrodes.

13. The semiconductor device of claim 1, wherein the first and second cell contact plugs include a metal-based material.
